(19) United States
(12) Patent Application Publication
(10) Pub. No.: US 2026/0214865 A1
(43) Pub. Date: Jul. 23, 2026

(54) INTELLIGENT LIQUID COOLING SYSTEM FOR ELECTRIC VEHICLE

(71) Applicant: ADEIA SEMICONDUCTOR TECHNOLOGIES LLC, San Jose, CA (US)

(72) Inventors: Kuo An Chao, Burbank, CA (US); Seung Kang, San Diego, CA (US)

(21) Appl. No.: 19/034,367

(22) Filed: Jan. 22, 2025

(51) Int. Cl. H05K 7/20; G01K 1/024; G01K 1/14; G01K 13/02; H01M 10/613; H01M 10/625; H01M 10/63; H01M 10/6569; H02J 50/00; H02J 50/10

(52) U.S. Cl. CPC H05K 7/20881; G01K 1/024; G01K 1/146; G01K 13/026; H01M 10/613; H01M 10/625; H01M 10/63; H01M 10/6569; H02J 50/005; H02J 50/10; H05K 7/20309; H05K 7/20327; H05K 7/20381

(57) ABSTRACT

Disclosed are intelligent liquid cooling systems for electric vehicles. The systems include a coolant circulation system, a sensor, and a controller. The coolant circulation system includes a coolant circulation path filled with a liquid coolant in thermal communication with a subsystem of the electric vehicle, and a coolant circulator to flow the liquid coolant through the coolant circulation path. The sensor is configured to be circulated through the coolant circulation path by the flowing liquid coolant, where the sensor is configured to sense localized physical conditions of the liquid coolant at different locations along the coolant circulation path. In addition, the sensor is in wireless communication with a controller. The controller is configured to receive signals from the sensor indicative of the localized physical conditions at the different locations and adjust a condition of the liquid coolant in response to the received signals.

### CROSS-REFERENCE TO RELATED APPLICATION

This application is related to a U.S. non-provisional patent application titled “INTELLIGENT LIQUID COOLING SYSTEM FOR DATA CENTER,” filed on the same date as the present application, the entirety of which is incorporated herein by reference.

### TECHNICAL FIELD

This disclosure generally relates to an intelligent liquid cooling system, and more particular to an intelligent liquid cooling system for vehicles (e.g., electric vehicles).

### BACKGROUND

Cooling systems with circulating liquid across the source of the heat-generating hardware components have been used in various applications. These applications can include data centers and servers, personal computers, industrial electronics, and the automotive industry, among others. Generally, these cooling systems utilize liquid cooling by circulating the liquid along the liquid circulation paths that are disposed adjacent to the heat-generating hardware components. These paths are filled with a liquid which absorbs and dissipates the heat generated by the hardware components.

### SUMMARY

In one aspect, an intelligent liquid cooling system for an electric vehicle comprises a coolant circulation system, a sensor, and a controller. The coolant circulation system comprises a coolant circulation path filled with a liquid coolant in thermal communication with a first subsystem of the electric vehicle and a coolant circulator to flow the liquid coolant through the coolant circulation path. The sensor is configured to be circulated through the coolant circulation path by the flowing liquid coolant, where the sensor is further configured to sense localized physical conditions of the liquid coolant at different locations along the coolant circulation path, and the sensor is in wireless communication with a controller. The controller is configured to receive signals from the sensor indicative of the localized physical conditions at the different locations and adjust the condition of the liquid coolant in response to the received signals.

In another aspect, an intelligent liquid cooling system for an electric vehicle comprises a plurality of coolant circulation systems, a plurality of sensors, and a controller. Each of the plurality of coolant circulation systems comprises a coolant circulation path filled with a liquid coolant in thermal communication with a corresponding subsystem of a plurality of subsystems included in the electric vehicle and a coolant circulator to flow the liquid coolant through the coolant circulation path. Each of the plurality of sensors is configured to be circulated through a corresponding coolant circulation path of a corresponding coolant circulation system by a flowing liquid coolant of the corresponding coolant circulation path, and each sensor is configured to sense localized physical conditions of the liquid coolant at different locations along the corresponding coolant circulation path, where each sensor is in wireless communication with a controller. The controller is configured to receive signals from the plurality of sensors, where each received signal is indicative of the localized physical conditions of the associated liquid coolant at the different locations and adjusts the condition of the associated liquid coolant in response to the received signals.

In another aspect, an electric vehicle comprises a coolant circulation system, a sensor, and a controller. The coolant circulation system comprises a coolant circulation path filled with a liquid coolant in thermal communication with a subsystem of the electric vehicle and a coolant circulator to flow the liquid coolant through the coolant circulation path. The sensor is to be circulated through the coolant circulation path by the flowing liquid coolant, and the sensor is configured to sense localized physical conditions of the liquid coolant at different locations along the coolant circulation path, where the sensor is in wireless communication with a controller. The controller is configured to receive signals from the sensor indicative of the localized physical conditions at the different locations and adjust a condition of the liquid coolant in response to the received signals.

### BRIEF DESCRIPTION OF THE DRAWINGS

The following detailed description of illustrative embodiments, is better understood when read in conjunction with the appended drawings. For the purpose of illustrating the present disclosure, exemplary constructions of the disclosure are shown in the drawings. Moreover, those skilled in the art will understand that the drawings are not to scale. Wherever possible, like elements have been indicated by identical numbers. The detailed description of embodiments and the embodiments set forth in the drawings present various descriptions of specific embodiments of the invention. However, the invention can be embodied in a multitude of different ways. It will be understood that certain embodiments can include more elements than illustrated in a drawing and/or a subset of the elements illustrated in a drawing. Further, some embodiments can incorporate any suitable combination of features from two or more drawings. The present disclosure is not limited to specific methods and apparatus disclosed herein.

FIG. 1 illustrates an example embodiment of an intelligent liquid cooling system, according to an embodiment.

FIG. 2A illustrates an example embodiment of a sensor for the intelligent liquid cooling system, according to an embodiment.

FIG. 2B illustrates an example block diagram of an integrated circuit component coupled to a sensor of the intelligent liquid cooling system, according to an embodiment.

FIG. 3 illustrates an example block diagram of a controller of the intelligent liquid cooling system, according to an embodiment.

FIG. 4 illustrates an example embodiment of an intelligent liquid cooling system implemented in an electric vehicle, according to an embodiment.

FIG. 5 illustrates an example embodiment of a vehicle machine learning model, according to an embodiment.

FIG. 6 illustrates an example embodiment of a data center, according to an embodiment.

FIG. 7 illustrates an example embodiment of an intelligent liquid cooling system implemented in a data center, according to an embodiment.

FIG. 8 illustrates an example of an additional coolant circulation system configured with a wireless charging pathway, according to an embodiment.

FIG. 9 illustrates an example of utilizing a wireless charging pad to charge the sensor of the intelligent liquid cooling system, according to an embodiment.

FIG. 10 illustrates an example embodiment of a data center machine learning model, according to an embodiment.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features.

Some cooling systems include a liquid reservoir for storing the cooling liquid and a liquid circulation control system that controls the flow of the cooling liquid, e.g., flow rate. For instance, a pump is disposed in the liquid circulation paths to flow the liquid from the reservoir into the liquid circulation paths, and vice versa. This can ensure consistent thermal management and prevent overheating of the hardware components. However, in spite of the technological development in the field of the cooling systems, a continuing demand for optimizing the performance of these cooling systems poses technical limitations. For example, continuing technological trends in the performance of hardware components in various applications, such as the data centers and servers, personal computers, industrial electronics, and an automotive industry, and the like, demand increasing heat dissipation performance, increasing heat dissipation efficiency (e.g., balancing energy use with heat dissipation needs), and innovative approaches for optimizing (e.g., preventing overloading some portions or liquid paths with excessive heat) heat dissipation across the hardware components. For example, such innovative approaches are needed to optimize the heat dissipation by preventing specific portions or liquid paths from being overloaded with excessive heat, which could compromise system reliability and efficiency. Accordingly, there is a need for improved cooling systems to meet the growing thermal management demands of modern applications while optimizing performance and energy consumption.

Various industries, such as an automotive industry, a cloud computing service industry, or other industries related to developing or operating hardware components, having heat dissipation as their critical performance characteristics, are experiencing a surge in demand for enhanced heat dissipation management.

For example, the automotive industry is experiencing increasing demand for the implementation of advanced electrical hardware components in vehicles. For instance, there is a significant shift toward electric vehicles (EVs), hybrid vehicles, and autonomous driving systems. These trends demand the integration of high-capacity batteries, electrical motors, and power electronics into vehicles, all of which generate substantial heat during operation. Effective dissipation of this heat can be the critical for ensuring the performance and safety of these components. For example, vehicle batteries produce considerable heat during operation, and inadequate heat dissipation can compromise battery performance and pose safety risks, such as fire hazards. While the batteries being charged may generate substantial heat, the other electrical and mechanical systems may not. On the other hand, when the electric vehicle is in motion, all systems may generate heat at different levels. As such, individualized cooling systems that target different subsystems, e.g., the secondary battery system, the electrical system, and the mechanical system, can greatly enhance the effectiveness and efficiency of the vehicle cooling system. To address these challenges, the automotive industry has focused on developing advanced heat dissipation systems to enhance cooling efficiency.

The cloud computing service industry is also experiencing a surge in demand for enhanced cooling optimization due to the increasing reliance on data centers to provide computing resources for remote users (e.g., subscribers). These users access cloud systems via the internet to utilize computing resources offered by service providers. The rapid growth in the number of remote users and the increasing complexity of workloads processed by these resources have created significant challenges in thermal management. This trend is particularly evident in areas such as artificial intelligence (AI), machine learning (ML), high-performance computing (HPC), and advanced cloud systems. These applications demand substantial processing power to handle vast amounts of data, generating significant heat during operation. Effective heat dissipation is critical to maintaining the performance, reliability, and safety of data centers. Inadequate cooling not only degrades computing performance but also increases the risk of hardware failures and safety hazards, such as thermal runaway in critical components. Analogous to the electric vehicle application, while certain functional units, such as computing devices, may generate substantial heat when a data center is performing computation-centric tasks, while other systems, such as memory devices may generate less heat. On the other hand, other functional units, such as memory devices, may generate substantial heat when the data center is performing data retrieval-centric tasks, while other systems, such as compute devices, may generate less heat. As such, individualized cooling systems that target different subsystems, e.g., the compute devices and memory devices, can enhance the effectiveness and efficiency of the data center cooling system.

To meet these demands of modern automotive and cloud computing service technical trends, an advanced intelligent liquid cooling system (hereinafter “an intelligent liquid cooling system”) that advances beyond traditional cooling approaches by implementing dynamic and intelligent cooling solutions is demanded. For example, such an intelligent liquid cooling system may be able to monitor localized heat patterns and adjust coolant distribution in real time, ensuring optimal performance, energy efficiency, and safety in the vehicle and data center operations.

To address these and other needs, according to embodiments, the present disclosure is directed to an intelligent liquid cooling system. The intelligent liquid cooling system is configured to dissipate heat generated from various types of hardware components or systems. The intelligent liquid cooling system includes one or more coolant circulating paths and one or more sensors that circulate along with the coolant flowing through the paths. One or more sensors are communicatively coupled to a controller. Specifically, the intelligent liquid cooling system is configured such that the sensors measure (e.g., sense) local characteristics of the coolant and transmit the measured characteristics to the controller, and the controller causes the circulation of the coolant in the coolant circulating paths to be adjusted by analyzing the measured (e.g., sensed) characteristics.

### Introduction of Intelligent Liquid Cooling System

Intelligent liquid cooling systems, as disclosed herein, are designed to dissipate heat generated by hardware components in various applications, such as electrical components of a vehicle (e.g., an electric vehicle), data centers, and other environments that demand effective thermal management. The intelligent liquid cooling system uses a coolant as the primary medium for heat dissipation, where the coolant is circulating via a coolant circulation path. In some examples, the coolant circulation path is configured on or near the surface of heat-generating hardware components, such as electrical components of the vehicle and/or hardware components included in a data center. As coolant flows through this path, it absorbs heat from the components and removes it from the hardware components and/or the system.

To enhance the efficiency of heat dissipation, the coolant circulation path is designed with specific patterns, such as zigzag or winding configurations, to increase the coverage of the hardware surface and optimize cooling performance. This coolant circulation path can be constructed from thermally conductive materials that enable efficient heat transfer. These materials are well-known and widely available in the field of thermal management, and the present disclosure does not limit the types of materials.

The coolant used in intelligent liquid cooling systems is a thermally conductive fluid that is specifically designed to absorb and transfer heat. Such coolants are commercially available and commonly used across various industries, and the present disclosure does not limit the types and materials of the coolant. The intelligent liquid cooling system includes a coolant reservoir connected to the coolant circulation path. For example, the coolant enters the coolant circulation path from the reservoir through an inlet and exits back into the reservoir via an outlet. The inlet acts as the interface through which the coolant flows into the coolant circulation path, while the outlet serves as the interface through which the heated coolant returns to the reservoir.

The flow rate of the coolant (e.g., coolant circulation rate) within the coolant circulation path is technically tied with the intelligent liquid cooling system's heat dissipation performance. For example, a higher coolant flow rate facilitates faster heat removal from hardware components by ensuring that heated coolant is quickly replaced with cooler fluid from the reservoir. This can significantly improve cooling performance by maintaining hardware components within their normal operating temperature ranges. However, increasing the coolant flow rate also introduces tradeoffs. A higher flow rate can demand more energy to pump the coolant, reducing the overall energy efficiency of the system. This creates a design challenge in which the intelligent liquid cooling system needs to balance effective heat dissipation with energy efficiency.

The disclosed intelligent liquid cooling systems are designed with a focus on optimizing heat dissipation while minimizing energy consumption. This involves ensuring that heat is dissipated uniformly across the coolant circulation path, preventing localized overheating or hot spots. Accumulated heat in specific portions of the coolant circulation path can cause hardware components to operate outside their normal temperature ranges, leading to reduced performance or even hardware damage. For example, if a hardware component has a normal operating temperature range of 60 to 70 degrees Celsius, the intelligent liquid cooling system may need to manage the physical condition (e.g., coolant temperature and flow rate) to ensure that the component stays within this range during operation.

In the relevant technical field, a coolant circulation systems are generally utilized to dissipate heat generated from the hardware components of the system. Traditional coolant circulation systems, however, have significant technical limitations in optimizing heat dissipation. For example, the coolant circulation system typically manages cooling by monitoring the flow rate of coolant at the inlet of the coolant path, where the coolant flows into the coolant path. While this approach can provide basic thermal management, it results in uneven heat distribution, with certain areas of the hardware component experiencing localized overheating. Additionally, the traditional coolant circulation system lacks the ability to dynamically adjust the coolant flow to address specific hot spots of the hardware components. This limitation reduces their efficiency and effectiveness in managing the thermal demands of modern hardware.

Furthermore, traditional coolant circulation system fails to optimize energy usage. For example, increasing the coolant flow rate to improve cooling performance can lead to excessive energy consumption, which negatively impacts overall system efficiency. For example, in the traditional coolant circulation systems, the coolant path flows through multiple hardware components, which limits the system's ability to efficiently optimize heat dissipation, such that if one of hardware components is experiencing higher temperature, the traditional coolant circulation systems may need to increase the coolant flow rate across the multiple hardware components. For instance, a traditional coolant circulation system in a vehicle is designed to manage heat generated by various components, such as the battery pack, the electric motor, and other heat-generating hardware. If the battery pack operates at a temperature above its normal range while other components remain within their normal operating temperatures, the system may need to increase the overall coolant flow rate. This adjustment may need more energy (e.g., additional power to pump the coolant), unnecessarily increasing the flow rate across components that do not demand extra cooling, thereby wasting energy. Moreover, traditional coolant circulation systems are not able to optimize heat dissipation effectively. Typically, these systems monitor the coolant temperature at the inlet and/or outlet of the coolant path. If the temperature deviates from normal operating ranges, the system adjusts the coolant flow rate accordingly. However, such systems cannot dynamically control the coolant flow to address localized hot spots within the coolant path. For example, in a battery pack composed of multiple cells, one cell may experience abnormal operation, generating excessive heat and forming a localized hot spot. The traditional system may fail to detect this issue because it monitors only the coolant temperature at the inlet and/or outlet, which might still reflect normal operating conditions. As a result, the system does not adjust the coolant flow to target the hot spot. This allows heat to accumulate in the affected cell, potentially leading to battery malfunction, reduced lifespan, or, in extreme cases, thermal runaway and fire. This inability to detect and respond to localized hot spots highlights a significant limitation of traditional coolant circulation systems, underscoring the need for advanced thermal management technologies capable of dynamic and precise heat dissipation.

In a data center, the traditional coolant circulation systems are used to manage heat dissipation for various types of computing resources, such as processing units, memory units, and other hardware components assembled in multiple racks of the data center. For example, the coolant pathway is designed to pass over the surfaces of these components across the racks to dissipate the heat they generate. However, in such systems, the coolant pathway typically flows through multiple hardware components in sequence, limiting the system's ability to efficiently optimize heat dissipation. For instance, if one server rack or processing unit generates excessive heat while other components remain within their normal operating temperature range, the system may need to increase the overall coolant flow rate to address the hot component. This approach increases energy consumption unnecessarily, as the coolant flow rate across components operating within normal temperature ranges is also increased, consuming additional power without corresponding benefit. Traditional coolant circulation systems in data centers often rely on temperature monitoring at the inlet and/or outlet of the coolant path. If the sensed coolant temperature deviates from normal operating ranges, the system may increase or decrease the coolant flow rate. However, these systems lack the ability to dynamically control the coolant flow rate to address localized hot spots within the data center. For example, a specific processing unit within a server rack may experience abnormal operation, generating excessive heat and creating a hot spot. The traditional system may fail to detect this localized issue if the overall inlet and/or outlet coolant temperatures remain within acceptable limits. As a result, the system does not adjust the coolant flow rate to target the hot spot, allowing heat to accumulate. This accumulation can lead to hardware malfunctions or even catastrophic failures, such as damage to the processing unit or overheating of adjacent components. The inability to detect and address hot spots dynamically reduces the system's efficiency and increases the risk of equipment failure, emphasizing the need for more advanced thermal management solutions in data center environments.

To address these and other needs of the traditional coolant circulation systems, aspects of the present disclosure provide various embodiments of intelligent liquid cooling systems that can manage the operating of the intelligent liquid cooling system by incorporating real-time temperature monitoring and adaptive flow control, enabling the intelligent liquid cooling system to dynamically detect and respond to localized heat variations. By achieving more precise and efficient cooling, the intelligent liquid cooling system can enhance performance and energy efficiency, meeting the growing demands of applications such as vehicles (e.g., electric vehicles) and data center operations.

In some embodiments, the disclosed intelligent liquid cooling system is designed to dynamically control the coolant circulation rate for each localized heat-generating hardware component. For instance, the intelligent liquid cooling system may include one or more coolant circulation paths, with each path configured on or near the surface of a specific hardware component.

In applications where the intelligent liquid cooling system is used in a vehicle, individual coolant circulation paths can be implemented on or near the surface of each heat-generating hardware component, such as a battery, an electric motor, or other components generating significant heat. In other applications, such as data centers, the coolant circulation system can be specifically designed to dissipate heat generated by computing resource components. Each coolant circulation path can be configured on or near the surface of hardware, such as processing units, memory units, or other components that produce heat.

By localizing heat dissipation to individual hardware components, this approach enhances energy efficiency. For example, if one hardware component operates above its normal temperature range and may need increased cooling performance, the intelligent liquid cooling system can increase the coolant circulation rate for the specific path associated with that component. Meanwhile, coolant circulation rates for other components operating within their normal temperature ranges remain unchanged, optimizing overall energy usage and system performance.

In various embodiments, the disclosed intelligent liquid cooling system includes multiple sensors integrated into a networked architecture to monitor and optimize coolant circulation. Each coolant circulation path within the intelligent liquid cooling system can include one or more sensors that actively circulate with the coolant. These sensors are configured to sense localized physical conditions of the coolant at different locations along the coolant circulation path. In some examples, the physical conditions can include one or more of the temperatures and the flow rate of the liquid coolant. In some examples, as disclosed herein, the different locations can include locations adjacent to and in thermal communication with the subsystem.

For example, as the coolant flows through the coolant circulation path, the sensors also circulate within the same path. During this movement, each sensor senses the temperature and pressure of the coolant at different locations. The sensors are equipped with communication capabilities, allowing them to transmit the sensed localized physical conditions, along with their corresponding locations, to a controller. This transmission occurs in real-time or near real-time, enabling continuous monitoring of the coolant's thermal state.

The intelligent liquid cooling system also includes a controller designed to manage the heat dissipation profile of the coolant in each circulation path. The heat dissipation profile may include various elements, such as coolant temperature, coolant circulation rate, the amount of coolant in the path, and the direction of coolant circulation. The specific elements to be controlled are application dependent. For example, one application may demand managing only coolant temperature and circulation rate, while another may involve all listed elements.

In some embodiments, the controller receives the sensed coolant localized physical conditions and locations from the sensors and analyzes this data to determine the thermal behavior of the system. By mapping temperature and pressure sensing to specific locations within the coolant circulation path, the controller can identify localized issues, such as potential hot spots. For instance, in a data center application, the intelligent liquid cooling system might include a circulation path configured to cool an array of central processing units (CPUs) on a processing unit. Each CPU generates heat that must be dissipated to maintain optimal performance. Sensors circulating within the coolant path sense temperature and pressure at various points and transmit this data to the controller. If the controller detects that a specific location within the path corresponds to a sensed temperature or pressure exceeding the normal operating range of a CPU, it identifies this area as a hot spot.

In some embodiments, to address this localized heat accumulation, the controller can dynamically adjust the coolant physical conditions (e.g., temperature and/or flow rate) in the affected section of the path. This adjustment might involve increasing the circulation rate, redirecting coolant flow, or altering the amount of coolant in the path. These targeted changes prevent further heat accumulation at the hot spot while maintaining efficient cooling across the entire system in the data center. Unlike traditional systems that rely on overall inlet and outlet temperatures, this approach enables granular, location-specific thermal management. By detecting and addressing localized heat issues, the disclosed intelligent liquid cooling system improves heat dissipation efficiency, reduces energy consumption, and ensures the reliable operation of heat-generating components, even under variable workload conditions.

In some embodiments, the disclosed intelligent liquid cooling system may incorporate a machine learning model to optimize the heat dissipation performance of the intelligent liquid cooling system. For example, the controller can store the machine learning model and utilize the machine learning model to determine controlling parameters of the elements (e.g., the coolant temperature, the coolant circulating rate, the amount of coolant, and/or the coolant circulation direction) of heat dissipation profile. The machine learning model, as disclosed herein, can also be referred to as a master-slave model. The master-slave model operates as a distributed architecture where a central “master node” coordinates the operations of multiple “slave nodes.” The master node acts as the primary decision-maker, gathering data (e.g., coolant localized physical conditions sensed by the sensors) from the sensors deployed throughout the intelligent liquid cooling system. These sensors continuously monitor the coolant localized physical conditions, such as coolant temperature and coolant circulation rate at various points along the coolant circulation path. The machine learning model includes a plurality of slave nodes, and each slave node is designed to receive localized data from a sensor in its assigned coolant circulation path and analyze the heat dissipation profile of the assigned coolant circulation path. For instance, a slave node may predict temperature changes or coolant circulation rate requirements based on the predicted operation of the hardware component associated with the coolant circulation path. For example, if the coolant circulation path is implemented in a vehicle to dissipate heat generated from a battery of the vehicle, the slave node can predict temperature changes or coolant circulation rate requirements by analyzing the predicted vehicle usage pattern. For example, if the vehicle is predicted to charge the battery, the slave node can predict the coolant temperature and circulation rate demanded to charge the battery. In other examples, where the coolant circulation path is implemented in a data center to dissipate heat generated from a particular processor (e.g., CPU), the slave node can predict the usage pattern of the processor, and predict the requirement of the coolant temperature and circulation rate based on the usage pattern. For example, if the usage pattern indicates that the workload intensity of the particular processor is higher during a specific time range, the slave node can predict the requirement of the coolant temperature and circulation rate during the specific time range based on the predicted workload intensity of the particular processor. The master node collects the predictions and analyses from all the slave nodes and synthesizes this information to form a global understanding of the system's thermal state. Based on the aggregated data, the master node dynamically adjusts the coolant flow rates across the system. For example, if one slave node identifies a hot spot near a battery cell of the vehicle battery (or a processor in the data center), the master node can increase the coolant flow rate to that region while reducing flow in less critical areas to optimize energy efficiency. The master-slave architecture incorporates a feedback loop to continuously refine its predictions and control strategies. As the master node executes adjustments to the coolant circulation, updated sensor data is sent back to the slave nodes, enabling them to recalibrate their predictions. This iterative process allows the system to adapt in real time to changing thermal conditions, ensuring that the cooling performance is optimized.

To facilitate an understanding of the systems discussed herein, several terms are described below. These terms and other terms used herein should be construed to include the provided descriptions, the ordinary and customary meanings of the terms, and/or any other implied meaning for the respective terms, wherein such construction is consistent with the context of the term. Thus, the descriptions below do not limit the meaning of these terms but only provide example descriptions.

A heat dissipation profile of a coolant can refer to an optimal coolant circulation parameter to efficiently dissipate the heat generated from the heat generating hardware component. For example, the heat dissipation profile can include a coolant temperature, a coolant circulation rate, an amount of coolant in the path, and/or a direction of coolant circulation. The heat dissipation profile varies based on an optimal operating temperature and the operational status of the corresponding hardware components.

A central processing unit (CPU) can refer to a processing component that performs the processing of data by executing instructions, such as performing basic arithmetic, logic control, and input/output operations in accordance with the instructions. The CPU can have various architectures that dictate how the CPU processes data, executes instructions and communicates with other parts of the computer system. However, the present disclosure does not limit the CPU architectures.

A tensor processing unit (TPU) can generally refer to a processing unit (e.g., a type of application-specific integrated circuit) specifically designed for accelerating machine learning workloads, such as handling computational requirements of machine learning models (for example, a deep learning algorithm). The TPU can include, without limiting, matrix multiplication units configured to perform matrix multiplications in accordance with the machine learning models, memory configured to support data transfer demanded for machine learning workloads, and the like.

A neural processing unit (NPU) can generally refer to a processing unit specifically designed for accelerating machine learning and artificial intelligence computations that involve neural networks. For example, the neural network can generally refer to a network having a plurality of nodes and layers, where each node (organized in specific layer(s)) processes data to perform the task, such as data patter reorganization, data classification, output predictions, and the like. The NPU is designed to perform specific types of mathematical operations used in the neural network. The NPU can include a plurality of processing cores configured to execute multiple operations in the neural network parallelly.

A graphics processing unit (GPU) can refer to a processing unit designed to accelerate graphics rendering. The GPU can include a plurality of cores configured to perform parallel processing. The GPU can have various architectures based on required operation, such as parallel processing. In addition, the GPU can be implemented as a stand-alone processing unit or integrated with other processing units, such as the CPU. The present disclosure does not limit the types of GPU architecture and implementation of the GPU.

### Intelligent Liquid Cooling System

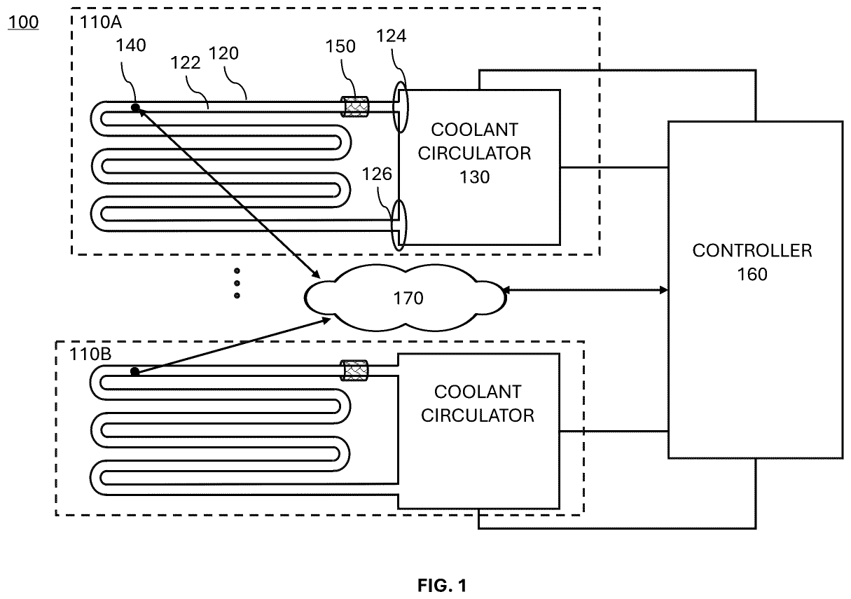

FIG. 1 illustrates an example embodiment of an intelligent liquid cooling system 100, as disclosed herein. As illustrated in FIG. 1, the intelligent liquid cooling system 100 can include one or more coolant circulation system 110A, 110B and a controller 160. Each coolant circulation system 110A, 110B includes a coolant circulation path 120, a coolant circulator 130, a sensor 140, and a wireless power transmitter 150. For the purpose of illustration, FIG. 1 illustrates an arrangement of specific numbers of coolant circulation system 110A, 110B, one coolant circulation path 120 included in each coolant circulation system 110A, 110B, one sensor 140 included in the coolant circulation path 120, and a coolant circulator 130. However, the present disclosure is not limited to this arrangement. For example, the intelligent liquid cooling system 100 can include one or more coolant circulation system 110A, 110B, more than one coolant circulation path 120 included in each coolant circulation system 110A, 110B, more than one sensor included in the coolant circulation path 120, and more than one coolant circulator 130. The specific arrangement of the intelligent liquid cooling system 100 can be dynamically determined based on specific application.

In some embodiments, each of the coolant circulation system 110A, 110B is configured to dissipate heat generated from one or more heat generating hardware components (hereinafter “hardware component”). The heat generating component, as disclosed herein, generally refer to a hardware component that generate the heat during its operation, where the generated heat can compromise the performance of the hardware component, thus, dissipation of the heat is demanded to maintain the optimal performance of the hardware component. Such hardware component can vary based on specific applications, and the present disclosure does not limit the types of applications and the types and numbers of hardware components included in the application.

As illustrated in FIG. 1, each coolant circulation system 110A and 110B includes a coolant circulation path 120, a coolant circulator 130, a sensor 140, and a wireless power transmitter 150. In certain embodiments, the coolant circulation path 120 is positioned on or near the surface of the associated hardware component to facilitate efficient heat dissipation. The coolant circulation path 120 can be configured to cover the surface area of the hardware component and may include patterns such as zigzag or winding formations. These patterns are designed to maximize surface coverage and optimize thermal transfer and can be tailored based on the specific shape and geometry of the hardware component. The present disclosure does not limit the design or formation of the coolant circulation path 120.

The coolant 122 (e.g., liquid coolant) circulating within the coolant circulation path 120 is a specially formulated liquid engineered to absorb, transfer, and dissipate heat generated by the hardware component. The coolant 122 is composed of materials with high thermal conductivity to ensure efficient heat transfer. The specific formulation of the coolant can be selected based on the requirements of the application, such as thermal capacity, viscosity, or operating temperature range. The present disclosure does not limit the types of the materials or the specific composition of the coolant 122.

In some embodiments, the circulation of coolant 122 within the coolant circulation path 120 can be controlled using the coolant circulator 130. As illustrated in FIG. 1, the inlet 124 and outlet 126 of the coolant circulation path 120 are connected to the coolant circulator 130, which manages the flow of the coolant through the coolant circulation path 120. The coolant circulator 130 may include various elements to control the coolant circulation effectively. For instance, the coolant circulator 130 can incorporate a coolant reservoir (not shown in FIG. 1) and a compressor (not shown in FIG. 1). In this configuration, the coolant reservoir stores the coolant 122, while the compressor pumps it into the inlet 124 of the coolant circulation path 120. For example, the coolant circulator 130 can circulate the coolant from the coolant reservoir into the inlet and return the coolant from the outlet back into the coolant reservoir. As the coolant 122 circulates through the coolant circulation path 120, the coolant 122 absorbs heat from the associated hardware component and exits via the outlet 126, returning to the reservoir. This setup allows the circulation rate of the coolant 122 to be dynamically controlled by adjusting the operational parameters of the compressor. For example, increasing the compressor speed or flow rate can pump the coolant 122 through the circulation path more quickly or in greater quantities, enabling precise control of the cooling performance. In addition to these components, the coolant circulator 130 may include other elements designed to enhance the efficiency of the cooling system. These could include components to cool the circulated coolant, such as a condenser, evaporator, or chiller. The inclusion and configuration of such additional components can be tailored to the specific application requirements without limitation.

As further illustrated in FIG. 1, the coolant 122 within the coolant circulation path 120 includes a sensor 140. The sensor 140 is designed to be circulated through the coolant circulation path 120 by the flowing the coolant 122. For instance, when the coolant 122 is circulating, the sensor 140 moves at the same or nearly the same rate as the coolant, corresponding to the coolant circulation rate. In this configuration, the sensor 140 is capable of sensing various coolant localized physical conditions, including one or more of the coolant temperature and pressure at the different locations along the coolant circulation path 120.

In some embodiments, the sensors 140 located in the coolant circulation system 110A and 110B are communicatively coupled with each other and also with the controller 160 via a network 170. In these examples, each sensor 140 continuously transmits the sensed localized physical condition (e.g., sensed coolant temperature and/or coolant pressure and sensed locations) at different locations along the coolant circulation path 120 to the controller 160 through the network 170. The network 170 can be implemented as a wireless communication network and may include various configurations depending on the application.

For instance, the network 170 can utilize direct communication channels by establishing a point-to-point wireless connection between each sensor 140 and the controller 160. Alternatively, the network 170 may function as a personal area network (PAN), which establishes short-range connections between the sensors in the intelligent liquid cooling system and the controller. Additionally, the network 170 can support short-range wireless communication protocols such as Bluetooth, which facilitates wireless communication over distances of up to approximately 10 meters. In other examples, the network 170 may employ Bluetooth Low Energy (BLE), a protocol optimized for lower power consumption and shorter coverage areas compared to standard Bluetooth. Further, Near Field Communication (NFC) can also be utilized, enabling wireless communication over short ranges, typically less than 1 meter.

By leveraging these communication methods, the system ensures that the sensors 140 can relay critical real-time data about the coolant's localized physical conditions at the different locations along the coolant circulation path 120. This data allows the controller 160 to monitor and dynamically manage the intelligent liquid cooling system for optimal thermal performance, adapting to changes in the hardware component's operating conditions.

In some embodiments, the controller 160 is configured to monitor coolant localized physical conditions, such as coolant temperature and/or coolant pressure, at various locations along the coolant circulation path 120. The controller 160 can analyze these sensed localized physical conditions, which are transmitted by the sensor 140 via the network 170, along with the corresponding location of the sensor. This analysis allows the controller to assess the thermal state of the coolant in real time and dynamically control the operation parameter of the coolant circulator 130 to ensure optimal cooling performance.

In some configurations, the controller 160 can store a pre-defined optimal heat dissipation profile for the coolant 122. This heat dissipation profile can serve as a reference for maintaining the hardware component's operation within its ideal operating range. The pre-defined optimal heat dissipation profile can be provided by a third party, such as an administrator, a hardware component manufacturer, or an operator of the hardware component, and is tailored to ensure the hardware component operates at its optimal performance. The heat dissipation profile can include parameters such as the optimal coolant temperature, coolant circulation rate, the required amount of coolant, and the preferred direction of coolant circulation.

In some cases, the optimal heat dissipation profile is stored as a template, enabling it to be associated with specific operational modes of the hardware component. For example, if the hardware component is a battery in a vehicle, the optimal heat dissipation profile can be defined based on the battery's operational state, such as discharging, charging, or high-intensity versus low-intensity operation. This ensures that the cooling system adapts to the varying thermal demands of the battery during different usage scenarios. Similarly, in data center applications, if the hardware component is a processing unit, the optimal heat dissipation profile can account for different computational intensities. For instance, the profile may include parameters tailored for high-intensive computations, standard workload operations, or low-intensity tasks. By associating these profiles with the processor's operational state, the system ensures efficient cooling tailored to the specific thermal requirements of the hardware. By integrating pre-defined heat dissipation profiles and real-time data analysis, the controller 160 dynamically adjusts the cooling system to maintain optimal thermal conditions, ensuring the performance, longevity, and energy efficiency of the hardware components under varying operational scenarios.

In some embodiments, the controller 160 is configured to determine whether the sensed coolant localized physical conditions align with the parameters defined in the optimal heat dissipation profile. For instance, the controller 160 can compare the sensed coolant temperature and pressure at various locations along the coolant circulation path 120 to the pre-defined coolant temperature and pressure specified in the optimal heat dissipation profile. This comparison allows the controller to assess whether the cooling system is operating within the desired thermal range for optimal performance.

Additionally, the controller 160 is designed to adjust the operational parameters of the coolant circulator 130 to maintain or restore compliance with the optimal heat dissipation profile. These parameters may include coolant flow rate, circulation direction, coolant temperature, and other related factors. For example, if the sensed coolant temperature exceeds the pre-defined optimal temperature (e.g., included in the heat dissipation profile), the controller 160 can increase the coolant flow rate by adjusting the operation of the compressor within the coolant circulator 130. This adjustment enhances heat dissipation, ensuring that the hardware component remains within its optimal operating temperature range. Conversely, if the sensed coolant temperature is below the pre-defined optimal temperature, the controller 160 can decrease the coolant flow rate by modulating the compressor's operation. By reducing the flow rate in such scenarios, the controller minimizes unnecessary energy expenditure, thereby improving the energy efficiency of the coolant circulator 130. This dynamic control enables the intelligent liquid cooling system 100 to adapt to varying thermal demands while optimizing both cooling performance and power consumption. Through these mechanisms, the controller 160 can ensure that the intelligent liquid cooling system operates effectively and efficiently, maintaining the thermal stability of hardware components under diverse operating conditions.

In some cases, the controller 160 is designed to optimize coolant circulation by preventing the formation of hot spots at specific positions along the coolant circulation path 120. In some embodiments, the controller 160 continuously monitor the coolant localized physical conditions, such as temperature and pressure, at various positions along the path. As sensors within the coolant circulation path 120 move and collect data, the controller 160 compares the sensed temperature and pressure at one position with those sensed at other positions along the path, as well as with the pre-defined optimal heat dissipation profile. This comparison is performed dynamically and in real time as new sensed data are received.

In scenarios where the sensed temperature or pressure at a specific location deviates significantly (e.g., above a pre-defined threshold deviation range) from values at other positions or from the optimal profile, the controller 160 can take corrective actions to mitigate the thermal anomaly and prevent the development of a hot spot. For example, if the temperature and pressure at a particular point exceed acceptable thresholds, the controller 160 can adjust the operational parameters of the coolant circulator 130. These adjustments may include increasing the coolant flow rate, increasing the amount of coolant delivered to the circulation path, or modifying the circulation direction to enhance heat dissipation at the affected location. By dynamically controlling these parameters, the intelligent liquid cooling system 100 prevents heat accumulation and maintains thermal balance across the circulation path.

In some embodiments, the controller 160 is also capable of determining an optimal heat dissipation profile for the coolant 122 without relying on external input from a third party. In these embodiments, the controller 160 utilizes a machine learning-based master-slave model, stored in its memory, to calculate the optimal profile and control the coolant circulator 130 accordingly. Each slave node in the master-slave model is assigned to manage heat dissipation of a specific hardware component and its corresponding coolant circulation system. For example, a slave node may be assigned to the coolant circulation system 110A responsible for dissipating heat generated by a battery in a vehicle. In this example, the slave model associated with the battery is trained to determine the optimal heat dissipation profile based on the operational status of the battery, such as charging or discharging. The model can also account for historical usage patterns of the hardware component. For instance, if historical data indicates that the vehicle is predominantly used between 8:00 AM and 9:00 AM, the heat dissipation profile for that time range may differ from profiles for less active periods. This allows the slave model to predict the heat dissipation profile of the battery, such as the temperature changes and coolant circulation requirements based on the expected operation of the battery during that time. The predictions and analyses from all slave nodes are aggregated by the master node, which synthesizes this information to form a global understanding of each hardware components assigned to the slave nodes. The master node dynamically adjusts coolant flow rates across the system to address specific thermal needs. For example, if a slave node identifies a hot spot near a battery cell in a vehicle battery or a processor in a data center, the master node can increase the coolant flow rate to that region while simultaneously reducing flow in less critical areas. This targeted approach ensures efficient cooling and optimized energy usage. The master-slave architecture also incorporates a feedback loop to enhance the system's adaptability. After the master node implements adjustments to the coolant circulation, updated sensor data is transmitted back to the slave nodes. This enables the slave nodes to recalibrate their predictions and refine their control strategies based on the observed effects of the adjustments. This iterative process allows the system to adapt dynamically to changing thermal conditions, ensuring that the cooling performance remains optimized in real time. By integrating machine learning-based predictive capabilities with real-time monitoring and adaptive control, the intelligent liquid cooling system 100 can ensure efficient and precise thermal management. The intelligent liquid cooling system 100 not only prevents localized overheating but also improves energy efficiency and maintains optimal operating conditions for the associated hardware components.

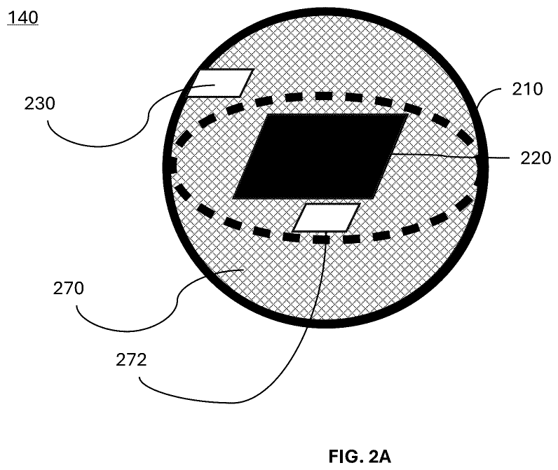

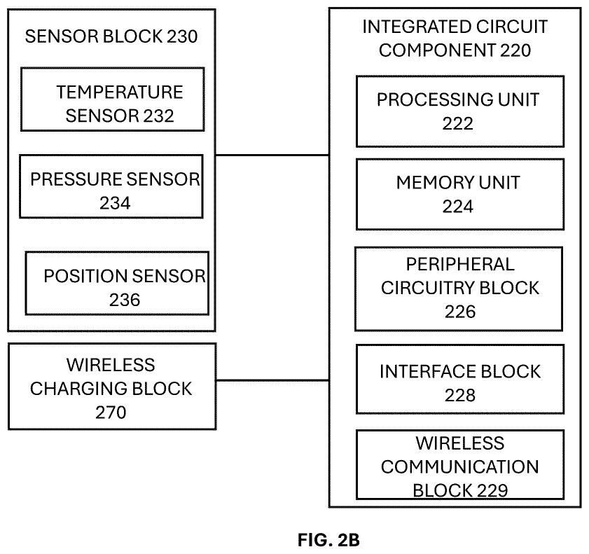

As further illustrated in FIG. 1, the intelligent liquid cooling system 100 includes a wireless power transmitter 150 designed to supply power to the sensor 140. In some embodiments, the sensor 140 is configured to receive wireless power and utilize it to operate its internal components, such as the sensor block and other electrical elements incorporated in the sensor 140 (e.g., as depicted in FIG. 2B). The wireless power transmitter 150 is positioned along a designated portion of the coolant circulation path 120, enabling wireless power transfer when the sensor 140 is brought into proximity. The wireless power transmitter 150 can include a transmitter coil surrounding the outer surface of a dedicated portion of the coolant circulation path 120. This transmitter coil is designed to receive alternating current (AC) or direct current (DC) from an external power source (not shown in FIG. 1). In scenarios where the power source supplies DC, the wireless power transmitter 150 incorporates circuitry to convert DC into AC, which is then used to generate an electromagnetic field. This electromagnetic field is capable of transferring energy wirelessly to the sensor 140 via electromagnetic coupling. The sensor 140, equipped with a receiving coil, captures this energy when positioned in the portion of the coolant circulation path 120 surrounded by the transmitter coil. For example, if the battery of the sensor 140 is needed for charging, the sensor 140 can send a message to the controller 160 to request battery charging. Upon receiving this request, the controller 160 can adjust the coolant flow rate to move the sensor 140 to the specific portion of the coolant circulation path 120 where the wireless power transmitter 150 is located. Once the sensor 140 is positioned in this area, the controller 160 can further control the coolant flow rate and flow direction to hold the sensor 140 in a stationary position during the charging process. The charging operation can continue until the sensor's battery (e.g., secondary battery 272 shown in FIG. 2A) reaches a threshold state of charge, at which point the controller 160 can resume normal coolant circulation.

Although FIG. 1 illustrates the wireless power transmitter 150 at a specific location along the coolant circulation path 120, the position of the transmitter can be adjusted to meet the requirements of specific applications. The transmitter can be installed at any point along the coolant circulation path 120 based on the intelligent liquid cooling system's operational needs. Additionally, the wireless power transmitter 150 can be integrated into the coolant circulator 130. In such a configuration, positioning the sensor 140 near or within the coolant circulator 130 would enable wireless power transfer. This arrangement can ensure that the sensor 140 remains powered and functional, facilitating continuous monitoring and operation within the intelligent liquid cooling system 100.

FIG. 2A illustrates an example embodiment of the sensor 140 as disclosed herein. In some examples, the sensor 140 is enclosed in an enclosure, where the surface 210 of the enclosure contacts the coolant. The enclosure prevents some components of the sensor, e.g., a secondary battery, control circuitry, communication circuitry, or power circuitry, from contacting the coolant. The enclosure can have any suitable shape, e.g., a spherical shape, and is designed to move along the coolant circulation path 120. In some embodiments, the surface 210 of the sensor 140 can incorporate various functional components, including a sensor block 230 and a wireless power receiver 270. As depicted in FIG. 2B, the sensor block 230 includes one or more of a temperature sensor 232, a pressure sensor 234, and a position sensor 236. The temperature sensor 232, as disclosed herein, can include, without limitation, a thermocouple sensor configured to generate voltage proportional to temperature difference, a resistance temperature detector configured to sense temperature by correlating the resistance of the temperature, a thermistor configured to sense resistance that varies depending on the temperature, and the like. The pressure sensor 234, as disclosed herein, can include, without limitation, a piezoelectric sensor configured to use piezoelectric to generate a voltage when pressure is applied to the piezoelectric, an optical sensor configured to use light to sense the pressure, and the like. The position sensor 236 can include, without limitation, an inertial sensor configured to sense the position of the sensor by using an accelerometer (e.g., configured to sense acceleration of the sensor), a magnetometer configured to sense the sensor position by utilizing magnetic fields, and the like.

In various embodiments, some features of the sensor block 230 may be suitably attached to the enclosure for enhanced sensitivity. However, embodiments are not so limited and in alternative embodiments, the sensor block 230 may be enclosed in the enclosure. In some embodiments, the wireless power receiver 270 is embedded within the surface 210 of the enclosure and can include a receiver coil configured to capture wireless power transmitted by the wireless power transmitter 150. In these embodiments, the sensor 140 includes a secondary battery 272 configured to receive the captured wireless power from the wireless power receiver 270, and the sensor 140 is powered by the secondary battery 272. The secondary battery 272 can include a lithium-ion battery, nickel-metal hydride battery, lead-acid battery, and the like, and the present disclosure does not limit the types of the secondary battery 272.

Depending on the configuration of the features of the sensor block 230 in relation to the enclosure, the enclosure may be formed of a suitable material for optimal functionality. For example, if the wireless power receiver 270 is enclosed in the enclosure, the enclosure is formed of a material that is transparent to the wireless power signal. In addition, if the temperature sensor is enclosed in the enclosure, the enclosure is formed of a material that has high thermal conductivity. Suitable materials can include certain electrical insulators that can have good thermal conductivity, e.g., certain polymers, ceramics, glasses, and composite materials.

In continued reference to FIG. 2A, in conjunction with FIG. 1, a transmitter coil of the wireless power transmitter 150 can be disposed of in sufficient proximity to the circulation path 120 to serve as a power transmitter coil for charging the secondary battery 272 of the sensor 140. For example, a portion of the coolant circulation path 120 can be surrounded by the transmitter coil of the wireless power transmitter 150 and configured as a charging station for the secondary battery 272 of the sensor 140. When the sensor 140 is positioned within the portion of the coolant circulation path 120 that is surrounded by the transmitter coil of the wireless power transmitter 150, electromagnetic coupling facilitates the transfer of power from the transmitter coil to the receiver coil in the wireless power receiver 270. In some cases, inside the sensor 140, an integrated circuit (IC) component 220 coordinates the operation of the various internal components. The sensor block 230 and the wireless power receiver 270 are connected to the IC component 220 through wired connections, enabling efficient communication and functionality. For the purpose of description, the sensor 140 is illustrated as implemented in a coolant circulation system. However, the sensor 140 can be implemented as a standalone element of the intelligent liquid cooling system. For example, the intelligent liquid cooling system, as disclosed herein, can include one or more coolant circulation systems (e.g., each coolant circulation system, including coolant circulation path and coolant circulator), one or more sensors, and a controller communicatively coupled with the one or more sensors.

FIG. 2B illustrates an example block diagram of the IC component 220. The IC component 220, as illustrated in FIG. 2B, can include a processing unit 222, a memory unit 224, a peripheral circuitry block 226, and an interface block 228. The processing unit 222, which includes a central processing unit (CPU), executes instructions stored in the memory unit 224, which can consist of non-volatile memory for retaining operational data and instructions.

In some embodiments, the instructions stored in the memory unit 224 enable the sensor 140 to perform various tasks. These include activating the sensor block 230 to sense coolant localized physical conditions such as temperature using the temperature sensor 232, pressure using the pressure sensor 234, and the position of the sensor using the position sensor 236. The sensed data is then transmitted to the controller 160 via the network 170, allowing the controller 160 to analyze and dynamically respond to real-time conditions. The IC component 220 also manages wireless charging by controlling the wireless power receiver 270 to receive power from the wireless power transmitter 150 when the sensor 140 is positioned appropriately within the coolant circulation path. In some examples, the IC component 220 further processes raw data from the sensor block 230 using the peripheral circuitry block 226. This preprocessing may involve filtering or converting the data into formats suitable for analysis by the controller 160. The interface block 228 facilitates communication between the sensor block 230, the peripheral circuitry block 226, and the external systems, including the controller 160. This arrangement can allow the sensor 140 to operate autonomously within the coolant circulation path 120, continuously monitoring thermal and positional parameters. By transmitting this data in real time, the sensor 140 enables the intelligent liquid cooling system 100 to dynamically adjust and optimize cooling performance, enhancing the efficiency and reliability of the system in diverse operational scenarios.

In some examples, the temperature sensor 232, the pressure sensor 234, and the position sensor 236 included in the sensor block 230 are configured to sense the coolant temperature, the pressure of the coolant within the coolant circulation path, and the position of the sensor 140, respectively. The sensed data from these sensors is processed further by the peripheral circuitry block 226 to ensure accuracy and usability before being transmitted or analyzed. The peripheral circuitry block 226 can include several specialized circuits, such as an analog-to-digital converter circuitry, a data acquisition circuitry, a sensor fusion circuitry, and a calibration circuitry. The analog-to-digital converter circuitry is designed to convert the analog signals generated by the temperature sensor 232, the pressure sensor 234, and the position sensor 236 into digital signals. This conversion is essential for further processing and integration with the digital systems of the intelligent liquid cooling system. The data acquisition circuitry is responsible for collecting the digital data produced by the analog-to-digital converter circuitry. In some examples, the data acquisition circuitry organizes this data systematically and, in some cases, applies filtering processes to remove noise from the collected data, improving its quality and reliability. For example, noisy or outlier data points may be excluded during this step to enhance the accuracy of subsequent analysis. The sensor fusion circuitry combines the digital data collected from the various sensors to generate a comprehensive representation of the coolant's state. By analyzing the temperature and pressure data alongside the positional data of the sensor 140, the sensor fusion circuitry can infer additional metrics, such as the coolant flow rate. The calibration circuitry ensures the accuracy and reliability of the sensors in the sensor block 230. For example, the calibration circuitry periodically compares the outputs of the temperature sensor 232, the pressure sensor 234, and the position sensor 236 against known reference values. If deviations beyond a predefined threshold are detected, the calibration circuitry adjusts the sensor parameters to correct for drift or inaccuracies. This ongoing calibration process helps maintain the precision and dependability of the sensors over time. By incorporating these functionalities, the peripheral circuitry block 226 ensures that the data collected from the sensor block 230 is accurate, well-organized, and meaningful, enabling effective monitoring and control of the coolant circulation path and overall performance of the intelligent liquid cooling system.

In some embodiments, the IC component 220 includes an interface block 228 designed to facilitate communication between the sensor 140 and the controller 160. The interface block 228 incorporates various data communication interfaces, such as a universal asynchronous receiver-transmitter (UART), a serial peripheral interface (SPI), and a mobile industry processor interface (MIPI). The UART enables asynchronous serial communication, transmitting data to the controller 160 over a single communication channel without requiring an external clock signal. The SPI is a synchronous serial communication protocol that allows communication between a master sensor and multiple slave sensors. For instance, in the intelligent liquid cooling system, the controller 160 can act as the master sensor, while the sensors in each coolant circulation path function as slave sensors. The MIPI standard provides high-speed communication, supporting data exchange between the sensor 140 and the controller 160.

The IC component 220 can also include additional hardware modules to enhance functionality, including a timer module, a voltage regulator module, and a security module. The timer module is configured to provide synchronization across the units and blocks of the IC component 220, ensuring coordinated operation. The voltage regulator module supplies stable voltage to various components, including the sensors in the sensor block 230, the wireless charging block 270, and all units and blocks within the IC component 220. For example, the wireless charging block 270 can receive power wirelessly and charge the sensor's battery. The battery, in turn, powers the sensors in the sensor block 230 and the IC component 220. In this configuration, the voltage regulator module adjusts the battery's power output to meet the specific voltage requirements of each sensor and IC component block. The security module can ensure data integrity and confidentiality by encrypting data before transmission to the controller 160. The security module employs encryption algorithms, such as the advanced encryption standard (AES), to secure sensor data against unauthorized access. This module enhances the reliability of data communication between the sensor 140 and the controller 160.

Additionally, the IC component 220 may include a wireless communication block 229 to enable seamless wireless data transmission. The wireless communication block 229 consists of a radio frequency (RF) transceiver and an antenna. The RF transceiver modulates sensor data, whether directly from the sensor block 230 or processed data from the sensor fusion circuitry within the peripheral circuitry block 226, onto a carrier wave matching the resonant frequency of the antenna. The antenna then transmits the modulated signal, containing the sensor data, to the controller 160. In some configurations, the antenna is embedded within the surface of the sensor 140, with its resonant frequency tailored to the specific wireless communication protocol used in the network 170.

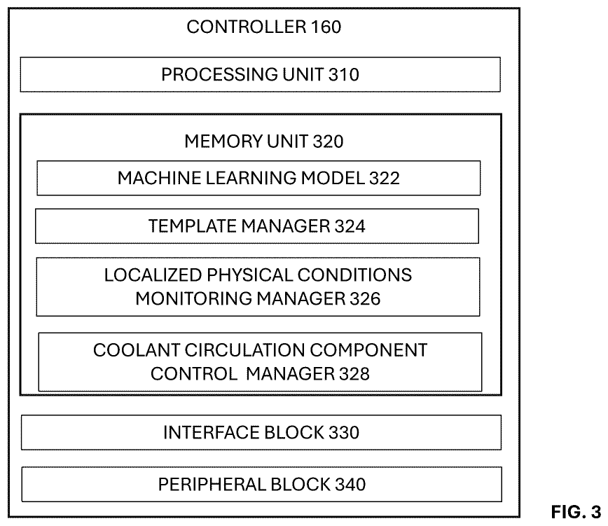

FIG. 3 illustrates an example block diagram of the controller 230. As illustrated in FIG. 3, the controller 230 can include a processing unit 310, a memory unit 320, an interface block 330, and a peripheral subsystem 340. In some embodiments, the processing unit 310, the memory unit 320, the interface block 330, and the peripheral subsystem 340 can be integrated as one or more silicon on chip (SoC) components.

The processing unit 310 can include various types of processing unit, such as the CPU, TPU, NPU, and GPU, and the processing unit 310 is configured to execute various instructions generated from the memory unit 320.

The memory unit 320 can include non-volatile memory and is configured to store various instructions to be executed by the processing unit 310. For instance, the memory unit 320 may store a machine learning model 322, a template manager 324, a coolant localized physical conditions monitoring manager 326, and a coolant circulator control manager 328.

In some scenarios, the heat dissipation profile of the coolant 122 defines optimal ranges for parameters such as coolant temperature, circulation rate, volume, and flow direction. This heat dissipation profile can change continuously based on the operational status of the associated hardware component. For example, if the hardware component is an electric motor in a vehicle operating at a slower speed, the heat dissipation profile may specify a lower coolant circulation rate because the motor generates less heat under such conditions. Conversely, if the motor operates at high speed, the heat dissipation profile would specify a higher coolant circulation rate to dissipate the increased heat generated by the motor. In another example, when the hardware component is a processing unit in a data center, the heat dissipation profile can adapt to the intensity of the processing unit's usage. For instance, during periods of high computational intensity, the heat dissipation profile may indicate a higher coolant circulation rate to address the increased thermal load. On the other hand, during low-intensity usage, the heat dissipation profile may adjust to a lower circulation rate to conserve energy while maintaining effective cooling.

By dynamically adjusting the heat dissipation profile in response to the hardware component's operational state, the memory unit 320, in conjunction with the processing unit 310 and other components of the controller 130, can ensure efficient and reliable cooling performance. This adaptability optimizes the thermal management of the system, maintaining hardware performance while minimizing energy consumption. In some embodiments, the heat dissipation profile of the coolant can be determined by either the machine learning model 322 or the template manager 324. The machine learning model 322 is configured to predict the heat dissipation profile dynamically based on historical and real-time data, while the template manager 324 provides pre-defined heat dissipation profiles tailored to the operational statuses of the hardware components.

In some embodiments, the machine learning model 322 is designed to train on data related to the hardware component's thermal behavior and utilize this trained data to generate precise heat dissipation profiles. The machine learning model 322 can operate as a master-slave architecture, where the controller 160 functions as the master node, and each sensor 140 is assigned as a slave node. In this configuration, the master node aggregates data collected by the slave nodes, such as coolant localized physical conditions (e.g., temperature and pressure) sensed by the sensors 140. Each slave node is trained to predict the heat dissipation profile specific to the hardware component it monitors. For instance, a slave node assigned to a vehicle battery may predict the heat dissipation profile based on historical charging and discharging cycles of the battery. Similarly, for a processing unit in a data center, the heat dissipation profile can be determined by analyzing historical workload intensity or usage patterns. These predictions allow the system to adjust cooling parameters proactively, ensuring efficient thermal management.

In some cases, the slave nodes are trained to determine the heat dissipation profile by analyzing the physical and thermal characteristics of the coolant. These characteristics may include viscous diffusion (the flow behavior of the coolant within the circulation path), thermal diffusion (the spread of heat within the coolant), convective heat transfer (heat transferred through the motion of the coolant), conductive heat transfer (heat transferred within the coolant without motion), and the coolant circulation pattern (e.g., laminar, or turbulent flow). By analyzing sensed coolant temperature and pressure at various locations along the coolant circulation path 120, the slave node can infer these characteristics and incorporate them into the determination of the heat dissipation profile. For example, if the slave node identifies a low viscous diffusion coupled with high thermal diffusion, the heat dissipation profile may recommend a lower coolant circulation rate, as the heat can be effectively dissipated through thermal diffusion alone. Conversely, if the coolant exhibits low conductive heat transfer and high convective heat transfer, the heat dissipation profile may suggest increasing the coolant circulation rate to prevent localized heat accumulation in areas of the coolant circulation path where conductive heat transfer is insufficient. By accounting for both the operational conditions of the hardware components and the dynamic physical properties of the coolant, the machine learning model 322 provides a highly adaptive and precise determination of the heat dissipation profile.

In some embodiments, the template manager 324 includes various heat dissipation profiles associated with hardware components. In some examples, individual heat dissipation profile is associated with specific hardware component and its operational mode such that a specific operational mode of each hardware component can include a corresponding heat dissipation profile. For example, if the hardware component is an electric motor used in a vehicle, the electric motor can be associated with a plurality of heat dissipation profiles, each heat dissipation profile is associated with a specific operational mode, such as higher intensive mode, lower intensive mode, idling mode, parking mode, and the like. In another example, if the hardware component is a processing unit installed in a data center, the processing unit can be associated with a plurality of heat dissipation profiles, where each heat dissipation profile is associated with a specific operational mode, such as higher intensive computation mode, lower intensive computation mode, and the like. In these embodiments, the heat dissipation profile is provided by a third party, such as an administrator, a hardware component manufacturer, or an operator of the hardware component. In some cases, the third party can update the heat dissipation profiles stored in the template manager 324 by accessing to the controller 160.

As illustrated in FIG. 3, the memory unit 320 further includes a coolant localized physical conditions monitoring manager 326. The coolant localized physical conditions monitoring manager 326 is configured to monitor the sensed coolant temperature (e.g., sensed by the temperature sensor 232) and the sensed coolant pressure (e.g., sensed by the pressure sensor 234) in various positions along the coolant circulation path 120 (e.g., the position sensed by the position sensor 236). In some embodiments, the coolant localized physical conditions monitoring manager 326 is configured to determine whether the sensed coolant localized physical conditions align with the parameters defined in the heat dissipation profile (e.g., generated by the machine learning model 322 and/or stored in the template manager 324). For instance, the coolant localized physical conditions monitoring manager 326 can compare the sensed coolant temperature and pressure at various locations along the coolant circulation path 120 to the pre-defined coolant temperature and pressure specified in the heat dissipation profile. This comparison allows the coolant localized physical conditions monitoring manager 326 to assess whether the cooling system is operating within the desired thermal range for optimal performance.

The memory further includes a coolant circulator control manager 328. The coolant circulator control manager 328 is designed to adjust the operational parameters of the coolant circulator 130 to maintain or restore compliance with the heat dissipation profile. For example, if the sensed coolant temperature exceeds the pre-defined optimal temperature (e.g., included in the heat dissipation profile), the coolant circulator control manager 328 can increase the coolant flow rate by adjusting the operation of the compressor within the coolant circulator 130. Conversely, if the sensed coolant temperature is below the pre-defined optimal temperature, the coolant circulator control manager 328 can decrease the coolant flow rate by modulating the compressor's operation.

In some embodiments, the controller 160 includes an interface block 330. The interface block 330 incorporates various data communication interfaces, such as the UART, SPI, and MIPI, and utilizes one of these communication interfaces to wirelessly communicate with the sensors 140.

In some embodiments, the controller 160 also includes a peripheral subsystem 340. The peripheral subsystem 340 can include modules, such as a timer module, a voltage regulator module, and a security module. The timer module is configured to provide synchronization across the processing unit 310, the memory unit 320, and the interface block 330, ensuring time synchronization. The voltage regulator module supplies stable voltage to the controller 160. The voltage regulator module adjusts the supplied voltage to meet the specific voltage requirements of the processing unit 310, the memory unit 320, and the interface block 330. The security module can decrypt the data received from the sensors 140. For example, the received data is encrypted with the AES algorithm, and the security module can decrypt the encrypted data.

### Intelligent Liquid Cooling System Adapted for Electric Vehicle

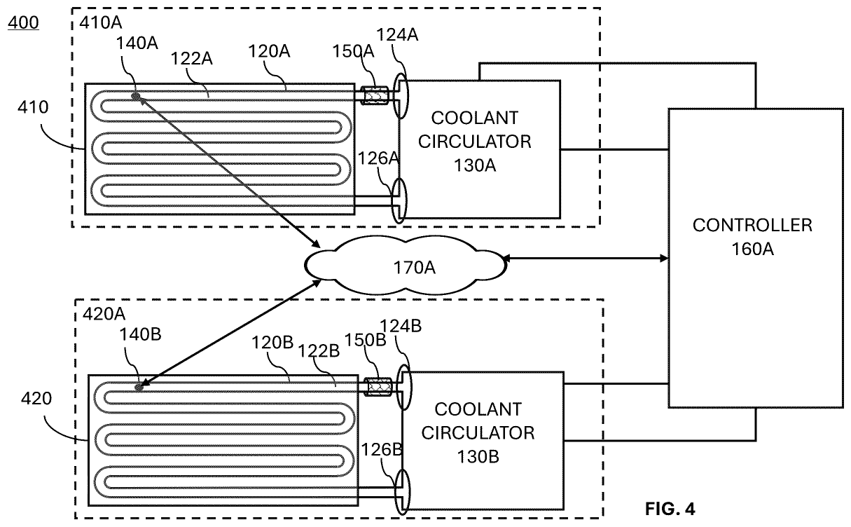

FIG. 4 illustrates an example embodiment of an intelligent liquid cooling system 400 implemented in a vehicle (e.g., electric vehicle). As shown in FIG. 4, the intelligent liquid cooling system 400 includes a first coolant circulation system 410A, a second coolant circulation system 420A, sensors 140, and a controller 160A. Each coolant circulation system is configured to manage the condition of liquid coolants as they flow through coolant circulation paths that pass surfaces of the subsystems of the vehicle. The condition of liquid coolant can include one or both of the temperature and pressure of the coolant. In some examples, each subsystem is configured to be at different temperatures relative to other subsystems during the operation of the vehicle.

The subsystem can include vehicle components that generate heat during its operation. For example, the subsystem can include a battery system that includes a plurality of secondary battery packs. In this example, each battery pack is in thermal communication with the liquid coolant (e.g., the liquid coolant dissipates heat generated from the battery pack). The subsystem can also include an electric motor, power electronics (e.g., inverters, converters), the transmission system, auxiliary systems, and other heat-generating elements within the vehicle. In some examples, the first coolant circulation system 410A is designed to dissipate heat generated by a secondary battery system 410. In some embodiments, the intelligent liquid cooling system 400 can also include a second coolant circulation system 420A for dissipating heat generated by an electrical component 420 of the electric vehicle. For example, the electrical component 420 can include an electric motor. In some examples, the secondary battery system 410 and the electrical component 420 can be configured to be at different temperatures relative to each other during the operation of the electric vehicle. Although the intelligent liquid cooling system 400 is illustrated here with the coolant circulation system assigned to the secondary battery system 410 and the electrical component 420, this configuration is provided merely as an example. The present disclosure does not limit the number or types of hardware components in the vehicle, nor on the number of coolant circulation systems. For instance, the intelligent liquid cooling system 400 can include multiple coolant circulation systems that each coolant circulation system can be integrated to manage heat dissipation for other vehicle components, such as power electronics (e.g., inverters, converters), the transmission system, auxiliary systems, and other heat-generating elements within the vehicle. Thus, the intelligent liquid cooling system, as disclosed herein, is designed to scale flexibly based on the specific thermal management needs of the vehicle, allowing for the integration of multiple hardware components and corresponding coolant circulation system as required.

As illustrated in FIG. 4, the first coolant circulation system 410A includes several components: a coolant circulation path 120A, coolant 122A circulating within the path, a coolant circulator 130A, a sensor 140A, and a wireless power transmitter 150A. These elements are similar to the coolant circulation path 120, coolant 122, coolant circulator 130, sensor 140, and wireless power transmitter 150 depicted in FIGS. 1, 2A, and 2B.

The coolant circulation path 120A is designed to traverse the surface of the secondary battery system 410. While the path is shown with a zigzag pattern for illustrative purposes, it can be customized to conform to the curvature or geometry of the secondary battery system 410. The formation of the path is not limited to any specific pattern, allowing for flexibility based on the design requirements of the hardware component.

The coolant 122A and sensor 140A circulate within the coolant circulation path 120A. Since the sensor 140A moves along with the coolant 122A, its movement depends on the coolant circulation rate (e.g., flow rate) and the direction of circulation. The sensor 140A is equipped with sensors to sense at least one of the temperature and pressure of the coolant (e.g., the localized physical condition of the coolant) at the different locations. The different locations include locations adjacent and in thermal communication with different ones of the secondary battery packs. For instance, the temperature sensor 232, the pressure sensor 234, and the position sensor 236 can sense the temperature and pressure of the coolant at the different locations and provide real-time data (sensed temperature and pressure of the coolant and location of the sensor) to the controller 160A via the network 170. This network 170A is same as the network 170 illustrated in FIG. 1, and for the purpose of brevity, this description of the network 170A is not repeated herein.

In some embodiments, the secondary battery system 410 is a packed battery, including an array of individual battery cells. The coolant circulation path 120A is configured to pass over the surface of the battery pack, specifically covering the surfaces of individual battery cells. If one of the battery cells generates higher heat than others, the sensor 140A can detect this anomaly by measuring a localized temperature increase as it passes the corresponding region of the coolant circulation path 120A. The sensed temperature, pressure, and location data are transmitted to the controller 160A, enabling it to identify hot spots within the circulation path. Upon detecting a hot spot, the controller 160A can adjust the operational parameters of the coolant circulator 130A to mitigate the issue, such as increasing the coolant circulation rate to dissipate the heat more effectively.

The circulation of coolant 122A within the coolant circulation path 120A is managed by the coolant circulator 130A. The coolant circulator 130A is connected to the inlet 124A and outlet 126A of the coolant circulation path 120A and controls the flow of coolant by regulating its sub-components. These sub-components may include a coolant reservoir, condenser, evaporator, compressor, and pump. In this system, the coolant reservoir serves as a storage unit for coolant 122A. The condenser removes heat from the coolant by transferring it to the surrounding air, ensuring that the coolant returning from the outlet 126A—typically heated after absorbing thermal energy from the secondary battery system 410—is cooled before being recirculated. Similarly, the evaporator can be used to remove heat, but it does so by utilizing a low-pressure gas to facilitate heat evaporation. The compressor increases the pressure of the coolant, enabling efficient circulation through the coolant circulation path 120A. The coolant circulation rate, or flow rate, can be adjusted by controlling the pressure generated by the compressor, as the two are often proportionally related. Finally, the pump introduces the coolant into the system through the inlet 124A, ensuring continuous flow throughout the circulation path.

As further illustrated in FIG. 4, the intelligent liquid cooling system 400 includes a wireless power transmitter 150A designed to supply power to the sensor 140A. The sensor 140A can be positioned in a specific area surrounded by the wireless power transmitter 150A to facilitate wireless power transfer. In some examples, the controller 160A is configured to control the operational parameters of the coolant circulator 130A to move the sensor 140A to this designated area for charging. In certain scenarios, the charging process may occur when the vehicle is parked, allowing the sensor 140A to charge its power without interrupting its operation within the coolant circulation path. The wireless power transmitter 150A is the same as the wireless power transmitter 150 illustrated in FIG. 1, and for the purpose of brevity, the description of the wireless power transmitter 150A is not repeated here.

As illustrated in FIG. 4, the second coolant circulation system 420A includes several components: a coolant circulation path 120B, coolant 122B circulating within the path, a coolant circulator 130B, a sensor 140B, and a wireless power transmitter 150B. These elements are similar to the coolant circulation path 120, coolant 122, coolant circulator 130, sensor 140, and wireless power transmitter 150 depicted in FIGS. 1, 2A, and 2B. In some embodiments, the wireless power transmitter 150B is designed to supply power to the sensor 140B. The sensor 140B can be positioned in a specific area surrounded by the wireless power transmitter 150B to facilitate wireless power transfer. In some examples, the controller 160B is configured to control the operational parameters of the coolant circulator 130B to move the sensor 140B to this designated area for charging. In certain scenarios, the charging process may occur when the vehicle is parked, allowing the sensor 140B to charge its power without interrupting its operation within the coolant circulation path. The wireless power transmitter 150B is the same as the wireless power transmitter 150 illustrated in FIG. 1, and for the sake of brevity, the description of the wireless power transmitter 150A is not repeated here.

The coolant circulation path 120B is designed to traverse the surface of a subsystem of a vehicle, for example, an electronic motor 420. While the path is shown with a zigzag pattern for illustrative purposes, it can be customized to conform to the curvature or geometry of the electronic motor 420. The formation of the path is not limited to any specific pattern, allowing for flexibility based on the design requirements of the hardware component.

The coolant 122B and sensor 140B circulate within the coolant circulation path 120B. Since the sensor 140B moves along with the coolant 122B, its movement depends on the coolant circulation rate (e.g., flow rate) and the direction of circulation. The sensor 140B is equipped with sensors to sense the temperature and pressure of the coolant, as well as its own location within the path. For instance, the temperature sensor 232, the pressure sensor 234, and the position sensor 236 can provide real-time data (sensed temperature and pressure of the coolant and location of the sensor) of the coolant to the controller 160A via the network 170A. This network 170A is same as the network 170 illustrated in FIG. 1, and for the purpose of brevity, this description of the network 170A is not repeated herein.

In some embodiments, the electronic motor 420 can include various sub-components, such as a rotor (e.g., rotating part of the motor to produce torque of the motor), a stator (e.g., generating rotating magnetic field to cause the rotor to rotate), an inverter (e.g., convert DC power received from a battery of the vehicle into AC to supply the AC into the electronic motor), an electronic motor controller (e.g., regulate the motor's speed, torque, and direction), to name a few without limitation. The coolant circulation path 120B is configured to pass over the surface of these sub-components of the electronic motor. If one of the sub-components generates higher heat than others, the sensor 140B can detect this anomaly by measuring a localized temperature increase as it passes the corresponding region of the coolant circulation path 120B. The sensed localized physical conditions of the coolant (e.g., temperature, pressure, and location data) are transmitted to the controller 160A via the network 170A, enabling the controller 160A to identify hot spots (e.g., the surface associated with the sub-component, generating the higher temperature) within the circulation path. Upon detecting a hot spot, the controller 160A can adjust the operational parameters of the coolant circulator 130A to mitigate the issue, such as increasing the coolant circulation rate to dissipate the heat more effectively. The coolant circulator 130B can be the same component as the coolant circulator 130B, and the detailed description of the coolant circulator 130A is not repeated herein. In some embodiments, the intelligent liquid cooling system 400 can include a single coolant circulator 130 connected to the first coolant circulation system 410A and a second coolant circulation system 420A.

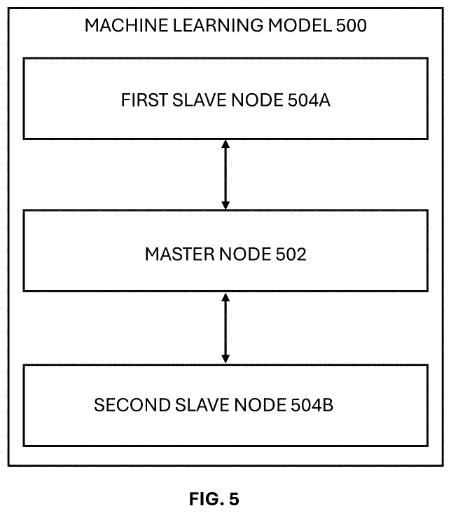

The controller 160A can have the same or similar elements, as illustrated in FIG. 3. Thus, the detailed description of the controller 160A is not repeated herein for the purpose of brevity. However, as will be illustrated in FIG. 5, in some examples, the controller 160A can incorporate a specifically tuned machine learning model (machine learning model 500, as illustrated in FIG. 5) to predict the heat dissipation profile of the secondary battery system 410 and the electronic motor 420.

FIG. 5 illustrates an example embodiment of a machine learning model 500, stored in the memory unit of controller 160A, as shown in FIG. 4. This machine learning model 500, referred to as the vehicle machine learning model 500, incorporates a machine learning algorithm implemented within a master-slave architecture. The algorithm is specifically tailored to optimize the operation of the intelligent liquid cooling system 400.

In the architecture depicted in FIG. 5, the controller 160A serves as the master node 502, while sensors 140A and 140B operate as the first slave node 504A and second slave node 504B, respectively. The master node 502 acts as a centralized decision-making unit, aggregating data collected by the slave nodes and using it to control the operational parameters of the coolant circulators 130A and 130B. The slave nodes collect data through the associated sensor (e.g., sensor 140A and 10B), such as sensed coolant temperature and pressure at various locations along the coolant circulation paths 120A and 120B. Additionally, the slave nodes generate predictions regarding the heat dissipation profiles of the associated hardware components, including the secondary battery system 410 (e.g., associated with the first slave node 504A) and the electric motor 420 (e.g., associated with the second slave node 504B). These heat dissipation profiles are dynamic and change based on the operational status of the respective components, with the predictions being continuously transmitted to the master node 502.

The first slave node 504A is associated with the secondary battery system 410 and is responsible for predicting the heat dissipation profile specific to the battery. The first slave node 504A performs the prediction by analyzing coolant characteristics and the operational status of the battery. Coolant characteristics are determined by assessing sensed localized physical conditions, such as temperature and pressure, at multiple points along the coolant circulation path 120A. These characteristics include viscous diffusion, thermal diffusion, convective heat transfer, conductive heat transfer, and the coolant circulation pattern, such as laminar or turbulent flow. The operational status of the battery, including parameters such as discharge rate, charge rate, and state of charge, is obtained from the vehicle's battery management system (BMS), which provides real-time monitoring data to the slave node. By combining these inputs, the first slave node 504A can predict the cooling requirements for the battery under varying operational conditions.

Similarly, the second slave node 504B is associated with the electric motor 420 and predicts its heat dissipation profile. This prediction is based on analyzing coolant characteristics, such as sensed temperature and pressure at different points along the coolant circulation path 120B, and the operational status of the motor. The coolant characteristics assessed include viscous diffusion, thermal diffusion, convective heat transfer, conductive heat transfer, and the circulation pattern. The operational status of the electric motor, such as acceleration, deceleration, or idling, is determined using data from the vehicle's electronic control unit (ECU) or a similar monitoring system. These combined data inputs allow the second slave node to dynamically predict the cooling requirements for the electric motor.

The master node 502 collects data from the sensors 140A and 140B, including sensed coolant localized physical conditions such as temperature and pressure at various locations along the coolant circulation paths, and combines this data with the predicted heat dissipation profiles generated by the first and second slave nodes 504A and 504B. Based on this aggregated information, the master node 502 adjusts the operational parameters of the coolant circulators 130A and 130B. These adjustments may involve controlling the speed of the compressor to regulate coolant pressure, managing the pump to control coolant flow rate, or adjusting the condenser and evaporator to control the inlet coolant temperature. For instance, if the coolant exhibits low viscous diffusion and high thermal diffusion, the master node 502 may reduce the coolant circulation rate, as heat can be dissipated effectively through thermal diffusion. Conversely, if the coolant shows low conductive heat transfer and high convective heat transfer, the master node may increase the circulation rate to prevent localized heat accumulation in areas of the coolant circulation paths where conductive heat transfer is insufficient.

### Example Embodiments of Intelligent Liquid Cooling System in Data Center

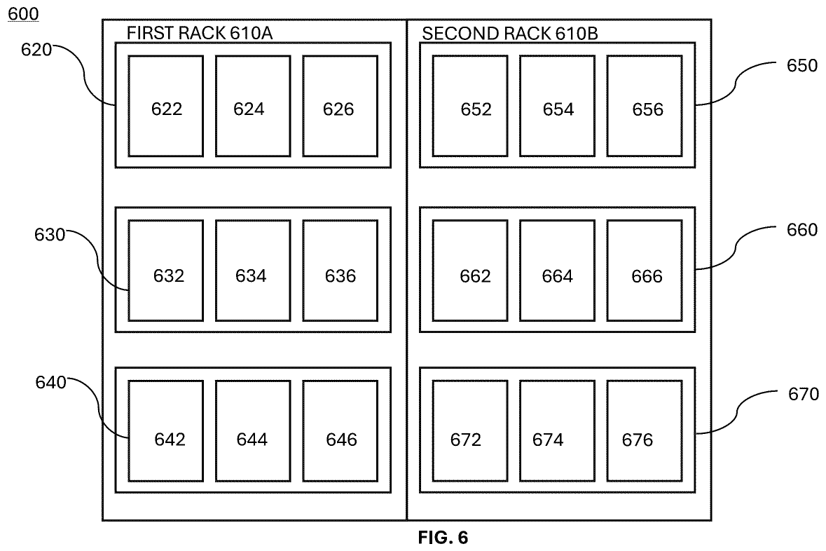

FIG. 6 illustrates an example embodiment of a data center 600 with a scalable and sophisticated architecture designed to handle diverse computational workloads, including cloud computing, big data analytics, and artificial intelligence applications. The data center 600 is composed of multiple racks that serve as modular enclosures hosting arrays of processing units, memory units, and peripheral units. While FIG. 6 depicts a first rack 610A and a second rack 610B, the data center 600 can include more than two racks, depending on specific operational requirements.

The racks 610A and 610B in the data center 600 provide modular platforms for integrating computational resources. For instance, the first rack 610A includes multiple boards, designated, for the purpose of description, as the first board 620, the second board 630, and the third board 640. Similarly, the second rack 610B includes additional boards, referred to as the fourth board 650, the fifth board 660, and the sixth board 670. Each board functions as a printed circuit board (PCB) that integrates components delivering computing resources.

Each board in the racks incorporates one or more compute subsystems, one or more memory subsystems, and one or more peripheral subsystems. For example, the first board 620 includes a compute subsystem 622, a memory subsystem 624, and a peripheral subsystem 626. Similarly, the second board 630 includes a compute subsystem 632, a memory subsystem 634, and a peripheral subsystem 636. The same architecture applies to the other boards in both racks. These components are interconnected to provide comprehensive computational, memory, and storage resources for diverse workloads. In some examples, each subsystem is configured to be at different temperatures relative to other subsystems during the operation of the data center.

The compute subsystems (e.g., 622, 632, 642, 652, 662, and 672) deliver computational capabilities and may include one or more compute dies, where each die is in thermal communication with the liquid coolant. In some examples, each die can include one or more central processing units (CPUs), one or more graphics processing units (GPUs), one or more tensor processing units (TPUs), one or more neural processing units (NPUs), or any combination thereof. Each of these compute subsystems can be configured flexibly, incorporating various numbers and types of CPUs, GPUs, TPUs, and NPUs based on workload demands. This flexibility ensures that the data center can efficiently support applications requiring general-purpose processing, parallel computing, or specialized acceleration.

The memory subsystems (e.g., 624, 634, 644, 654, 664, and 674) provide high-speed data access and temporary storage for their corresponding processing units. Each memory subsystem may include one or more memory dies, where each die is in thermal communication with the liquid coolant. In some examples, each die can include one or more static random access memory (SRAM), one or more dynamic random access memory (DRAM), one or more nonvolatile memory (NVM), and any combination thereof.

The peripheral subsystem (e.g., 626, 636, 646, 656, 666, and 676) delivers essential storage, interface, and networking capabilities. The storage unit in each peripheral subsystem may include solid-state drives (SSDs) and/or hard disk drives (HDDs) for persistent data storage. The interface unit manages input/output data, enabling seamless communication between processing units and external sensors accessing the data center's computational resources. The networking interface includes high-speed network adapters and switches, providing robust connectivity between units within the data center and external systems. These components collectively enable efficient data handling, high-speed communication, and reliable storage solutions. In some examples, the peripheral subsystem can include an interface subsystem, having one or more interfaces, where each interface is in thermal communication with the liquid coolant. In some examples, the peripheral subsystem can include a timing device subsystem, having one or more timing devices, where each timing device is in thermal communication with the liquid coolant.

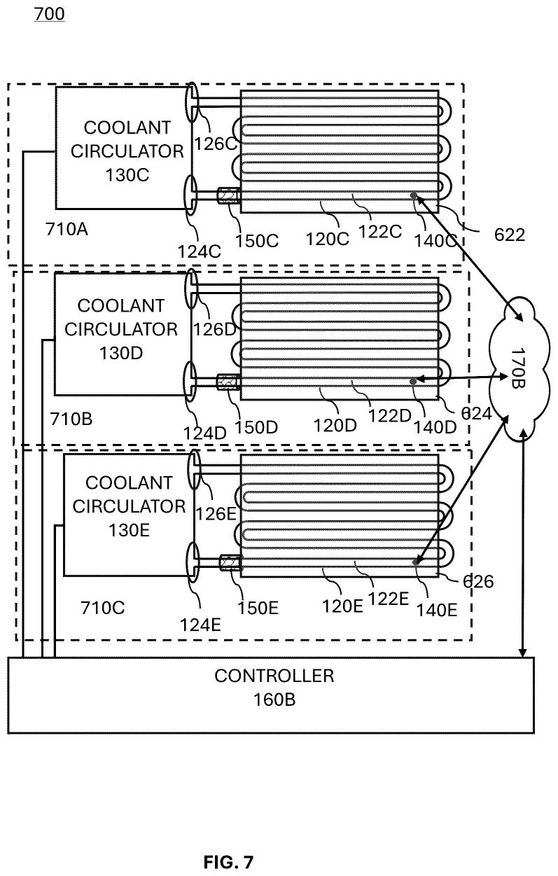

FIG. 7 illustrates an example embodiment of an intelligent liquid cooling system 700 implemented within a data center 600. As shown in FIG. 7, the intelligent liquid cooling system 400 includes a first coolant circulation system 710A, a second coolant circulation system 720B, a third coolant circulation system 720C, and a controller 160B communicatively coupled with the first, second, and third coolant circulation system 720A-720C. Each coolant circulation system is configured to manage the physical condition (e.g., coolant temperature and flow rate) of the corresponding coolant to ensure that the subsystems are operating within a normal temperature range.

In some examples, the intelligent liquid cooling system 700 can include one or more of the first coolant circulation system 710A, the second coolant circulation system 710B, and the third coolant circulation system 710C, where each coolant circulation system is configured to manage the physical condition of the corresponding coolant to ensure that the subsystems are operating within a normal temperature range. The first coolant circulation system 710A is designed to manage the physical condition of coolant that flows in a coolant circulation path associated with a compute subsystem 622 (e.g., one of subsystems of the data center), while the second coolant circulation system 720B is responsible to manage the physical condition of coolant that flows in a coolant circulation path associated with a memory subsystem 624 (e.g., another subsystem of the data center), and the third coolant circulation system 720C is responsible to manage the physical condition of coolant that flows in a coolant circulation path associated with a peripheral subsystem 626 (e.g., another subsystem of the data center). For the purpose of illustration, FIG. 7 illustrates the intelligent liquid cooling system 700 used in the blocks included in the first board 620 of the first rack 610A. However, the intelligent liquid cooling system 700 can also be used in other boards. In these examples, the first, second, and third coolant circulation system 710A, 710B, and 710C can ensure that each corresponding block of the data center operates within its optimal temperature range, enhancing performance, efficiency, and longevity.

As illustrated in FIG. 7, the first coolant circulation system 710A includes a coolant circulation path 120C, coolant 122C circulating within the path, a coolant circulator 130C, a sensor 140C, and a wireless power transmitter 150C. These elements are similar to the coolant circulation path 120, coolant 122, coolant circulator 130, sensor 140, and wireless power transmitter 150 depicted in FIGS. 1, 2A-2B, and 4.

The coolant circulation path 120C is designed to traverse the surface of the compute subsystem 622. While the path is shown with a zigzag pattern for illustrative purposes, it can be customized to conform to the curvature or geometry of the compute subsystem 622. The formation of the coolant circulation path is not limited to any specific pattern, allowing for flexibility based on the design requirements of the hardware component.

The coolant 122C and sensor 140C circulate within the coolant circulation path 120C. Since the sensor 140C moves along with the coolant 122C, its movement depends on the coolant circulation rate (e.g., flow rate) and the direction of circulation. The sensor 140C is equipped with sensors to sense the temperature and pressure of the coolant, as well as its own location within the path. For instance, the temperature sensor 232, the pressure sensor 234, and the position sensor 236 can provide real-time data (sensed temperature and pressure of the coolant and location of the sensor) of the coolant to the controller 160B via the network 170B. This network 170B is same as the network 170 illustrated in FIG. 1, and for the purpose of brevity, this description of the network 170A is not repeated herein.

In some embodiments, the compute subsystem 622 can include a plurality of processing units (e.g., array of processing units). The coolant circulation path 120C is configured to pass over the surface of the compute subsystem 622, specifically covering the surfaces of individual processing units. If one of the processing units generates higher heat than others, the sensor 140C can detect this anomaly by measuring a localized temperature increase as it passes the corresponding region of the coolant circulation path 120C. The sensed temperature, pressure, and location data are transmitted to the controller 160B via the network 170B, enabling it to identify hot spots within the circulation path. Upon detecting a hot spot, the controller 160B can adjust the operational parameters of the coolant circulator 130C to mitigate the issue, such as increasing the coolant circulation rate to dissipate the heat more effectively.

The circulation of coolant 122C within the coolant circulation path 120C is managed by the coolant circulator 130C. The coolant circulator 130C is connected to the inlet 124C and outlet 126C of the coolant circulation path 120C and controls the flow of coolant by regulating its sub-components. These sub-components may include a coolant reservoir, condenser, an evaporator, a compressor, and/or a pump. In this system, the coolant reservoir serves as a storage block for coolant 122C. The condenser removes heat from the coolant by transferring it to the surrounding air, ensuring that the coolant returning from the outlet 126C—typically heated after absorbing thermal energy from the compute subsystem 626—is cooled before being recirculated. Similarly, the evaporator can be used to remove heat, but it does so by utilizing a low-pressure gas to facilitate heat evaporation. The compressor increases the pressure of the coolant, enabling efficient circulation through the coolant circulation path 120C. The coolant circulation rate, or flow rate, can be adjusted by controlling the pressure generated by the compressor, as the two are often proportionally related. Finally, the pump introduces the coolant into the system through the inlet 124C, ensuring continuous flow throughout the circulation path.

As illustrated in FIG. 7, the second coolant circulation system 710B includes a coolant circulation path 120D, coolant 122D circulating within the path, a coolant circulator 130D, a sensor 140D, and a wireless power transmitter 150D. These elements are similar to the coolant circulation path 120, coolant 122, coolant circulator 130, sensor 140, and wireless power transmitter 150 depicted in FIGS. 1, 2A-2B, and 4.

The coolant circulation path 120D is designed to traverse the surface of the memory subsystem 624. While the path is shown with a zigzag pattern for illustrative purposes, it can be customized to conform to the curvature or geometry of the memory subsystem 624. The formation of the coolant circulation path is not limited to any specific pattern, allowing for flexibility based on the design requirements of the hardware component.

The coolant 122D and sensor 140D circulate within the coolant circulation path 120D. Since the sensor 140D moves along with the coolant 122D, its movement depends on the coolant circulation rate (e.g., flow rate) and the direction of circulation. The sensor 140D is equipped with sensors to sense the temperature and pressure of the coolant, as well as its own location within the path. For instance, the temperature sensor 232, the pressure sensor 234, and the position sensor 236 can provide real-time data (sensed temperature and pressure of the coolant and location of the sensor) of the coolant to the controller 160B via the network 170B.

In some embodiments, the memory subsystem 624 can include a plurality of memory units (e.g., array of memory units). The coolant circulation path 120D is configured to pass over the surface of the memory subsystem 624, specifically covering the surfaces of individual processing units. If one of the processing units generates higher heat than others, the sensor 140D can detect this anomaly by measuring a localized temperature increase as it passes the corresponding region of the coolant circulation path 120D. The sensed temperature, pressure, and location data are transmitted to the controller 160B via the network 170B, enabling it to identify hot spots within the circulation path. Upon detecting a hot spot, the controller 160B can adjust the operational parameters of the coolant circulator 130D to mitigate the issue, such as increasing the coolant circulation rate to dissipate the heat more effectively.

The circulation of coolant 122D within the coolant circulation path 120D is managed by the coolant circulator 130D. The coolant circulator 130D is connected to the inlet 124D and outlet 126D of the coolant circulation path 120D and controls the flow of coolant by regulating its sub-components. These sub-components may include a coolant reservoir, condenser, an evaporator, a compressor, and/or a pump. In this system, the coolant reservoir serves as a storage block for coolant 122D. The condenser removes heat from the coolant by transferring it to the surrounding air, ensuring that the coolant returning from the outlet 126D—typically heated after absorbing thermal energy from the memory subsystem 624—is cooled before being recirculated. Similarly, the evaporator can be used to remove heat, but it does so by utilizing a low-pressure gas to facilitate heat evaporation. The compressor increases the pressure of the coolant, enabling efficient circulation through the coolant circulation path 120D. The coolant circulation rate, or flow rate, can be adjusted by controlling the pressure generated by the compressor, as the two are often proportionally related. Finally, the pump introduces the coolant into the system through the inlet 124D, ensuring continuous flow throughout the circulation path.

As further illustrated in FIG. 7, the third coolant circulation system 710C includes a coolant circulation path 120E, coolant 122E circulating within the path, a coolant circulator 130E, a sensor 140E, and a wireless power transmitter 150E. These elements are similar to the coolant circulation path 120, coolant 122, coolant circulator 130, sensor 140, and wireless power transmitter 150 depicted in FIGS. 1, 2A-2B, and 4.

The coolant circulation path 120E is designed to traverse the surface of the peripheral subsystem 626. While the path is shown with a zigzag pattern for illustrative purposes, it can be customized to conform to the curvature or geometry of the peripheral subsystem 626. The formation of the coolant circulation path is not limited to any specific pattern, allowing for flexibility based on the design requirements of the hardware component.

The coolant 122E and sensor 140E circulate within the coolant circulation path 120E. Since the sensor 140E moves along with the coolant 122E, its movement depends on the coolant circulation rate (e.g., flow rate) and the direction of circulation. The sensor 140E is equipped with sensors to sense the temperature and pressure of the coolant, as well as its own location within the path. For instance, the temperature sensor 232, the pressure sensor 234, and the position sensor 236 can provide real-time data (sensed temperature and pressure of the coolant and location of the sensor) of the coolant to the controller 160B via the network 170B.

In some embodiments, the peripheral subsystem 626 can include a plurality of units, such as storage units, network interface units, and the like. The coolant circulation path 120E is configured to pass over the surface of the peripheral subsystem 626, specifically covering the surfaces of these units. If one of the units generates higher heat than others, the sensor 140E can detect this anomaly by measuring a localized temperature increase as it passes the corresponding region of the coolant circulation path 120E. The sensed temperature, pressure, and location data are transmitted to the controller 160B via the network 170B, enabling it to identify hot spots within the circulation path. Upon detecting a hot spot, the controller 160B can adjust the operational parameters of the coolant circulator 130E to mitigate the issue, such as increasing the coolant circulation rate to dissipate the heat more effectively.

The circulation of coolant 122E within the coolant circulation path 120E is managed by the coolant circulator 130E. The coolant circulator 130E is connected to the inlet 124E and outlet 126E of the coolant circulation path 120E and controls the flow of coolant by regulating its sub-components. These sub-components may include a coolant reservoir, condenser, an evaporator, a compressor, and/or a pump. In this system, the coolant reservoir serves as a storage block for coolant 122E. The condenser removes heat from the coolant by transferring it to the surrounding air, ensuring that the coolant returning from the outlet 126E typically heated after absorbing thermal energy from the peripheral subsystem 626-is cooled before being recirculated. Similarly, the evaporator can be used to remove heat, but it does so by utilizing a low-pressure gas to facilitate heat evaporation. The compressor increases the pressure of the coolant, enabling efficient circulation through the coolant circulation path 120E. The coolant circulation rate, or flow rate, can be adjusted by controlling the pressure generated by the compressor, as the two are often proportionally related. Finally, the pump introduces the coolant into the system through the inlet 124E, ensuring continuous flow throughout the circulation path.

As further illustrated in FIG. 7, each of the coolant circulation paths 120C, 120D, and 120E includes a dedicated portion with a wireless power transmitter 150C, 150D, and 150E, respectively. These wireless power transmitters are similar to the wireless power transmitter 150 described in FIG. 1, and for brevity, the detailed description of the wireless power transmitter is not repeated here.

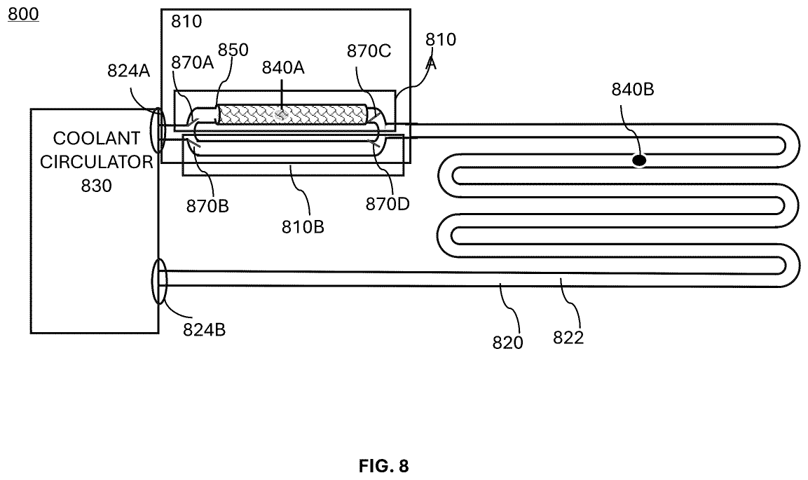

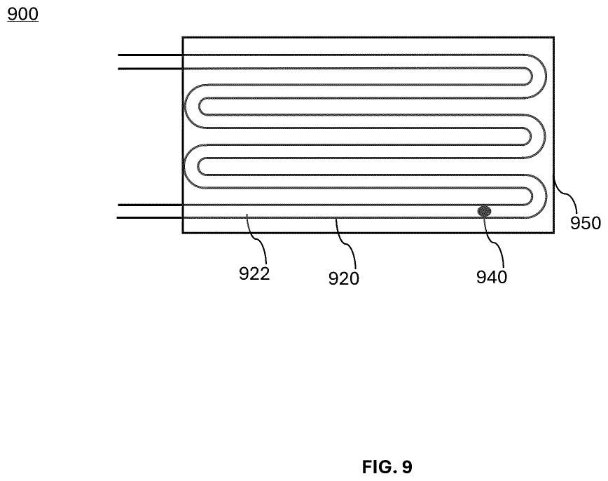

FIGS. 8 and 9 illustrate additional embodiments for charging sensors within the intelligent liquid cooling system. FIG. 8 shows an example of an additional coolant circulation system 800 configured with a wireless charging pathway 810. The wireless charging pathway 810 includes an upper path 810A and a lower path 810B, which diverge from the coolant circulation path 820 on one side of the wireless charging pathway and converge back into the coolant circulation path 820 on the opposite side. For example, coolant 822 flows from the coolant circulation path 820 through the inlet 824A into the upper and lower paths 810A and 810B and then reconverges into the coolant circulation path 820.

In some embodiments, one of the paths, such as the upper path 810A (or the lower path 810B), is surrounded by a wireless power transmitter 850. This wireless power transmitter 850 is similar to the wireless power transmitter 150 described earlier.

The coolant circulation system 800 may include two sensors, 840A and 840B, which are identical to the sensor 140 described in FIGS. 1, 2A, and 2B, and the detailed description of these sensors is not repeated here. In this configuration, one sensor, such as sensor 840A (or sensor 840B), can be stationary within the upper path 810A, while the other sensor 840B (or sensor 840A) circulates within the coolant circulation path 820. For instance, when the coolant 822 circulates through the coolant circulation path 820 (entering from inlet 824A and exiting via outlet 824B), the switches 870B and 870D are closed, and switches 870A and 870C are opened, directing sensor 840A into the upper path 810A. Once positioned within the upper path 810A, sensor 840A automatically receives wireless power from the wireless power transmitter 850.

When charging is complete, the switches 870A and 870C can close, and switches 870B and 870D can open, allowing sensor 840A to reenter the coolant circulation path 820. This process can be repeated whenever one of the sensors, 840A or 840B, requires charging. Each sensor can communicate its internal charge status to the controller 160B, enabling the controller to manage the coolant circulator 830 and operate switches 870A-870D to facilitate wireless charging. This additional coolant circulation system 800 can be implemented in the intelligent liquid cooling systems 100, 400, or 700.

FIG. 9 illustrates another embodiment utilizing a wireless charging pad 950 to charge the sensor. The wireless charging pad 950 is positioned either above or below the coolant circulation path 920, enabling continuous transmission of wireless power to the coolant circulation path. The sensor 940, circulating within the coolant circulation path 920, receives wireless power from the charging pad 950. The coolant circulation path 920, the coolant 922, and the sensor 940 are similar to the coolant circulation path 120, coolant 122, and sensor 140 described in FIGS. 1, 2A, and 2B, and their detailed descriptions are not repeated here.

In this embodiment, the wireless charging pad 950 can incorporate multiple transmitting coils arranged in a planar configuration. These coils, similar to those used in the wireless power transmitter 150, enable consistent and efficient wireless power transfer across the coolant circulation path, ensuring uninterrupted operation of the sensors circulating within the intelligent liquid cooling system.

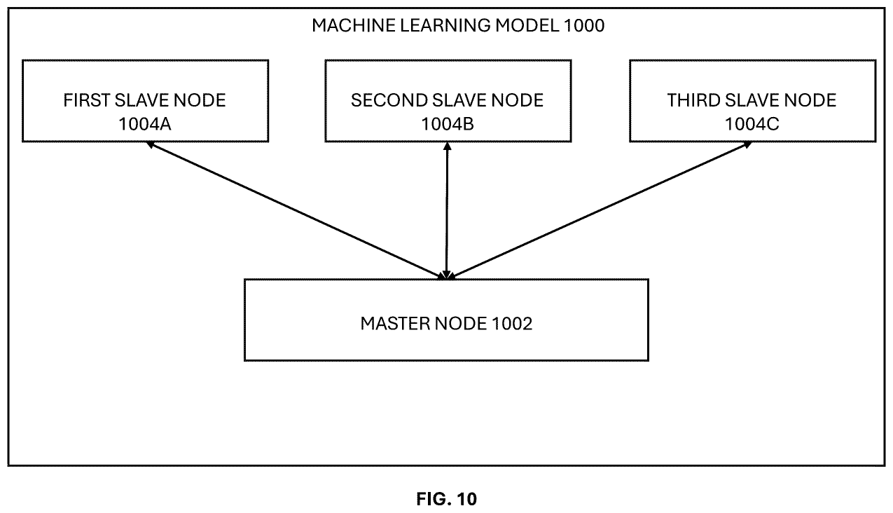

FIG. 10 illustrates an example embodiment of a machine learning model 1000, stored in the memory unit of controller 160B. This machine learning model 1000, referred to as a data center machine learning model 1000, incorporates a machine learning algorithm implemented within a master-slave architecture. The algorithm is specifically tailored to optimize the operation of the intelligent liquid cooling system 700.

In the architecture depicted in FIG. 10, the controller 160B serves as the master node 1002, while sensors 140C, 140D, and 140E operate as the first slave node 1004A, the second slave node 1004B, and the third slave node 1004C, respectively. The master node 1002 acts as a centralized decision-making unit, aggregating data collected by the slave nodes and using it to control the operational parameters of the coolant circulators 130C-130E. The slave nodes collect data through the associated sensor (e.g., sensors 140C-140E), such as sensed coolant temperature and pressure at various locations along the coolant circulation paths 120C-120E, respectively. Additionally, the slave nodes generate predictions regarding the heat dissipation profiles of the associated hardware components, including the compute subsystem 622 (e.g., associated with the first slave node 1004A), the memory subsystem 624 (e.g., associated with the second slave node 1004B) and the peripheral subsystem 626 (e.g., associated with the third slave node 1004C). These heat dissipation profiles are dynamic and change based on the operational status of the respective components, with the predictions being continuously transmitted to the master node 1002.

The first slave node 1004A is associated with the compute subsystem 622 and is responsible for predicting the heat dissipation profile specific to the compute subsystem 622. The first slave node 1004A performs the prediction by analyzing coolant characteristics and the operational status of the battery. Coolant characteristics are determined by assessing sensed localized physical conditions, such as temperature and pressure, at multiple points along the coolant circulation path 120C. These characteristics include viscous diffusion, thermal diffusion, convective heat transfer, conductive heat transfer, and the coolant circulation pattern, such as laminar or turbulent flow. The operational status of the compute subsystem 622, including parameters such as intensity of the usage of the compute subsystem 622, is obtained from a data center monitoring system (e.g., management system and the like), which provides real-time monitoring data to the slave node. By combining these inputs, the first slave node 1004A can predict the cooling requirements for the compute subsystem 622 under varying operational conditions.

Similarly, the second slave node 1004B is associated with the memory subsystem 624 and predicts its heat dissipation profile. This prediction is based on analyzing coolant characteristics, such as sensed temperature and pressure at different points along the coolant circulation path 120D, and the operational status of the memory subsystem 624. The coolant characteristics assessed include viscous diffusion, thermal diffusion, convective heat transfer, conductive heat transfer, and the circulation pattern. The operational status of the memory subsystem 624, such as the intensity of the memory subsystem 624 usage, is determined using data from the data center monitoring system (or any similar monitoring system). These combined data inputs allow the second slave node to dynamically predict the cooling requirements for the memory subsystem 624.

Similarly, the third slave node 1004C is associated with the peripheral subsystem 626 and predicts its heat dissipation profile. This prediction is based on analyzing coolant characteristics, such as sensed temperature and pressure at different points along the coolant circulation path 120E, and the operational status of the peripheral subsystem 626. The coolant characteristics assessed include viscous diffusion, thermal diffusion, convective heat transfer, conductive heat transfer, and the circulation pattern. The operational status of the peripheral subsystem 626, such as the intensity of the peripheral subsystem 626 usage, is determined using data from the data center monitoring system (or any similar monitoring system). These combined data inputs allow the second slave node to dynamically predict the cooling requirements for the peripheral subsystem 626.

The master node 1002 collects data from the sensors 140C-140E, including sensed coolant localized physical conditions such as temperature and pressure at various locations along the coolant circulation paths, and combines this data with the predicted heat dissipation profiles generated by the first, second, and third slave nodes 1004A-1004C. Based on this aggregated information, the master node 1002 adjusts the operational parameters of the coolant circulators 130C-130E, respectively. These adjustments may involve controlling the speed of the compressor to regulate coolant pressure, managing the pump to control coolant flow rate, or adjusting the condenser and evaporator to control the inlet coolant temperature. For instance, if the coolant exhibits low viscous diffusion and high thermal diffusion, the master node 1002 may reduce the coolant circulation rate, as heat can be dissipated effectively through thermal diffusion. Conversely, if the coolant shows low conductive heat transfer and high convective heat transfer, the master node may increase the circulation rate to prevent localized heat accumulation in areas of the coolant circulation paths where conductive heat transfer is insufficient.

### EXAMPLE EMBODIMENTS I

1. An intelligent liquid cooling system for an electric vehicle, the system comprising:
a coolant circulation system, comprising:
   a coolant circulation path filled with a liquid coolant in thermal communication with a first subsystem of the electric vehicle, and
   a coolant circulator to flow the liquid coolant through the coolant circulation path;
a sensor to be circulated through the coolant circulation path by the flowing liquid coolant, the sensor configured to sense localized physical conditions of the liquid coolant at different locations along the coolant circulation path, wherein the sensor is in wireless communication with a controller; and
the controller configured to receive signals from the sensor indicative of the localized physical conditions at the different locations and adjust a condition of the liquid coolant in response to the received signals.
2. An intelligent liquid cooling system for an electric vehicle, the system comprising:
a plurality of coolant circulation systems, each coolant circulation system comprising:
   a coolant circulation path filled with a liquid coolant in thermal communication with a corresponding subsystem of a plurality of subsystems included in the electric vehicle, and
   a coolant circulator to flow the liquid coolant through the coolant circulation path;
a plurality of sensors, each sensor configured to be circulated through a corresponding coolant circulation path of a corresponding coolant circulation system by a flowing liquid coolant of the corresponding coolant circulation path, the sensor configured to sense localized physical conditions of the liquid coolant at different locations along the corresponding coolant circulation path, wherein the sensor is in wireless communication with a controller; and
the controller configured to receive signals from the plurality of sensors, each received signal indicative of the localized physical conditions of associated liquid coolant at the different locations and adjust a condition of associated liquid coolant in response to the received signals.
3. The system of Embodiment 1, wherein the first subsystem comprises a secondary battery system including a plurality of secondary battery packs each in thermal communication with the liquid coolant.
4. The system of Embodiment 1 or 3, wherein the different locations include locations adjacent and in thermal communication with different ones of the secondary battery packs.
5. The system of Embodiment 1, wherein the intelligent liquid cooling system further comprises:
a second coolant circulation system, the second coolant circulation system comprising:
   a second coolant circulation path filled with a second liquid coolant in thermal communication with a second subsystem of the electric vehicle, and
   a second coolant circulator to flow the second liquid coolant through the second coolant circulation path;
a second sensor to be circulated through the second coolant circulation path by the flowing second liquid coolant, the second sensor configured to sense localized physical conditions of the second liquid coolant at different locations along the second circulation path, wherein the second sensor is in wireless communication with the controller; and
the controller configured to receive signals from the second sensor indicative of the localized physical conditions at the different locations along the second circulation path and adjust a condition of the second liquid coolant in response to the received signals from the second sensor.
6. The system of Embodiment 5, wherein the second subsystem comprises an electric component system, the second subsystem configured to be at different temperatures relative to the first subsystem during operation of the electric vehicle.
7. The system of any one of Embodiments 1 or 3-6, wherein the sensor comprises:
a sensor block comprising one or more of:
   a temperature sensor to measure a local temperature of the liquid coolant in contact with the sensor,
   a pressure sensor to measure a local pressure of the coolant in contact with the sensor, and
a position sensor to measure position of the sensor within the coolant circulation path; and a wireless communication block communicatively coupled with the controller via a wireless connection and configured to transmit data generated from the sensor block, the data comprising one or both of the local temperature and the local pressure measured by the sensor block and associated positions.
8. The system of any one of Embodiments 1 or 3-7, wherein the sensor is enclosed in an enclosure contacting the liquid coolant.
9. The system of Embodiment 8, wherein the enclosure has a spherical shape.
10. The system of Embodiment 8 or 9, wherein the sensor block is embedded on a surface of the enclosure.
11. The system of any one of Embodiments 1 or 3-10, wherein the sensor is powered by a secondary battery.
12. The system of Embodiment 11, wherein the secondary battery is enclosed in the enclosure.
13. The system of Embodiment 11, wherein a portion of the coolant circulation path is configured as a charging station for the secondary battery of the sensor.
14. The system of Embodiment 13, wherein the charging station comprises a wireless power transmitter, and wherein a transmitter coil of the wireless power transmitter is surrounding a dedicated portion of an outer surface of the coolant circulation path, the transmitter coil configured to transmit wireless power.
15. The system of Embodiment 14, wherein the sensor further comprises a wireless power receiver, the wireless power receiver comprising a receive coil configured to receive the transmitted wireless power.
16. The system of Embodiment 13, wherein the controller is further configured to control the flow of the liquid coolant to park the sensor to the charging station for charging the secondary battery of the sensor.
17. The system of any one of Embodiments 1 or 3-16, wherein the sensor comprises an antenna and a radio frequency system configured to establish the wireless communication with the controller.
18. The system of any one of Embodiments 1 or 3-17, the coolant circulation system further comprises an evaporator configured to remove heat from the liquid coolant.
19. The system of any one of Embodiments 1 or 3-18, wherein the controller is configured to identify a hot spot of the first subsystem by determining whether the sensed localized physical conditions at a specific location along the coolant circulation path is different from the sensed localized physical conditions at other locations of the subsystem.
20. The system of any one of Embodiments 1 or 3-19, wherein the sensor comprises an analog to digital converter, wherein the analog to digital converter is configured to convert the sensed physical conditions into digital signals to transmit to the controller.
21. The system of Embodiment 2, wherein the plurality of subsystems comprises a secondary battery system including a plurality of secondary battery packs each in thermal communication with the corresponding liquid coolant.
22. The system of Embodiment 21, wherein the different locations include locations adjacent and in thermal communication with different ones of the secondary battery packs.
23. The system of Embodiment 21 or 22, wherein the plurality of subsystems comprises an electric component system, the electric component subsystem configured to be at different temperatures relative to the secondary battery system during operation of the electric vehicle.
24. The system of Embodiment 2, wherein each sensor comprises:
a sensor block comprising one or more of:
   a temperature sensor to measure a local temperature of the liquid coolant in contact with the sensor,
   a pressure sensor to measure a local pressure of the coolant in contact with the sensor, and
   a position sensor to measure position of the sensor within the coolant circulation path; and
a wireless communication block communicatively coupled with the controller via a wireless connection and configured to transmit data generated from the sensor block, the data comprising one or both of the local temperature and the pressure measured by the sensor block and associated positions.
25. The system of Embodiment 2 or 24, wherein each sensor is powered by a secondary battery.
26. The system of any of Embodiments 2, 24, or 25, wherein each sensor is enclosed in an enclosure.
27. The system of Embodiment 26, wherein the enclosure has a spherical shape.
28. The system of Embodiment 26, wherein each sensor block is embedded on a surface of the enclosure.
29. The system of any one of Embodiments 2 or 21-28, wherein a portion of the coolant circulation path is configured as a charging station for the secondary battery of each sensor.
30. The system of Embodiment 29, wherein the charging station comprises a wireless power transmitter, and wherein a transmitter coil of the wireless power transmitter is surrounding a dedicated portion of an outer surface of the coolant circulation path, the transmitter coil configured to transmit wireless power.
31. The system of Embodiment 30, wherein each sensor further comprises a wireless power receiver, the wireless power receiver comprising a receive coil configured to receive the transmitted wireless power.
32. The system of any one of Embodiments 29-31, wherein the controller is further configured to control the flow of the liquid coolant to park each sensor to the charging station for charging the secondary battery of each sensor
33. The system of any one of the above Embodiments, wherein the localized physical conditions include one or both of a temperature and a pressure.
34. The system of any one of the above Embodiments, wherein the condition of the liquid coolant includes one or more of a temperature and a flow rate.
35. The system of any one of the above Embodiments, wherein the coolant circulation system further comprises:
a coolant reservoir to store the liquid coolant;
an inlet at one end of the coolant circulation path; and
an outlet at another end of the coolant circulation path,
wherein the coolant circulator is configured to circulate the liquid coolant from the coolant reservoir into the inlet and return the liquid coolant from the outlet back into the coolant reservoir.
36. An electric vehicle, comprising:
a coolant circulation system, comprising:
   a coolant circulation path filled with a liquid coolant in thermal communication with a subsystem of the electric vehicle, and
   a coolant circulator to flow the liquid coolant through the coolant circulation path;
a sensor to be circulated through the coolant circulation path by the flowing liquid coolant, the sensor configured to sense localized physical conditions of the liquid coolant at different locations along the coolant circulation path, wherein the sensor is in wireless communication with a controller; and
the controller configured to receive signals from the sensor indicative of the localized physical conditions at the different locations and adjust a condition of the liquid coolant in response to the received signals.
37. The vehicle of Embodiment 36, wherein the subsystem comprises a secondary battery system including a plurality of secondary battery packs each in thermal communication with the liquid coolant.
38. The vehicle of Embodiment 36 or 37, wherein the different locations include locations adjacent and in thermal communication with different ones of the secondary battery packs.
39. The vehicle of any one of Embodiments 36-38, wherein the localized physical conditions include one or both of a temperature and a pressure.
40. The vehicle of any one of Embodiments 36-39, wherein the condition of the liquid coolant includes one or more of a temperature and a flow rate.
41. The vehicle of Embodiment 36, further comprises:
a second coolant circulation system, the second the coolant circulation system comprising:
   a second coolant circulation path filled with a second liquid coolant in thermal communication with a second subsystem of the electric vehicle, and
   a second coolant circulator to flow the second liquid coolant through the second coolant circulation path;
a second sensor to be circulated through the second coolant circulation path by the flowing second liquid coolant, the second sensor configured to sense localized physical conditions of the second liquid coolant at different locations along the second circulation path, wherein the second sensor is in wireless communication with the controller; and
the controller configured to receive signals from the second sensor indicative of the localized physical conditions at the different locations along the second circulation path and adjust a condition of the second liquid coolant in response to the received signals from the second sensor.
42. The vehicle of Embodiment 41, wherein the second subsystem comprises an electric component system, the second subsystem configured to be at different temperatures relative to the subsystem during operation of the electric vehicle.
43. The vehicle of any one of Embodiments 36-42, wherein the coolant circulation system further comprises:
a coolant reservoir to store the liquid coolant;
an inlet at one end of the coolant circulation path; and
an outlet at another end of the coolant circulation path,
wherein the coolant circulator is configured to circulate the liquid coolant from the coolant reservoir into the inlet and return the liquid coolant from the outlet back into the coolant reservoir.
44. The vehicle of any one of Embodiments 36-43, wherein sensor comprises:
a sensor block comprising one or more of:
   a temperature sensor to measure a local temperature of the liquid coolant in contact with the sensor,
   a pressure sensor to measure a local pressure of the coolant in contact with the sensor, and
   a position sensor to measure position of the sensor within the coolant circulation path; and
a wireless communication block communicatively coupled with the controller via a wireless connection and configured to transmit data generated from the sensor block, the data comprising one or both of the local temperature and the local pressure measured by the sensor block and associated positions.
45. The vehicle of any one of Embodiments 36-44, wherein the sensor is enclosed in an enclosure contacting the liquid coolant.
46. The vehicle of any one of Embodiments 36-45, wherein the sensor is powered by a secondary battery.
47. The vehicle of Embodiment 46, wherein the secondary battery is enclosed in the enclosure.
48. The vehicle of any one of Embodiments 36-47, wherein the enclosure has a spherical shape.
49. The vehicle of any one of Embodiments 36-48, wherein the sensor block is embedded on a surface of the enclosure.
50. The vehicle of Embodiment 46, wherein a portion of the coolant circulation path is configured as a charging station for the secondary battery of the sensor.
51. The vehicle of Embodiment 50, wherein the charging station comprises a wireless power transmitter, and wherein a transmitter coil of the wireless power transmitter is surrounding a dedicated portion of an outer surface of the coolant circulation path, the transmitter coil configured to transmit wireless power.
52. The vehicle of Embodiment 51, wherein the sensor further comprises a wireless power receiver, the wireless power receiver comprising a receive coil configured to receive the transmitted wireless power.

### EXAMPLE EMBODIMENTS II

1. An intelligent liquid cooling system for a data center, the system comprising:
a coolant circulation system, comprising:
   a coolant circulation path filled with a liquid coolant in thermal communication with a first subsystem of the data center, and
   a coolant circulator to flow the liquid coolant through the coolant circulation path;
a sensor to be circulated through the coolant circulation path by the flowing liquid coolant, the sensor configured to sense localized physical conditions of the liquid coolant at different locations along the coolant circulation path, wherein the sensor is in wireless communication with a controller; and
the controller configured to receive signals from the sensor indicative of the localized physical conditions at the different locations and adjust a condition of the liquid coolant in response to the received signals.
2. An intelligent liquid cooling system for a data center, the system comprising:
a plurality of coolant circulation systems, each coolant circulation system comprising:
   a coolant circulation path filled with a liquid coolant in thermal communication with a corresponding subsystem of a plurality of subsystems included in the data center, and
   a coolant circulator to flow the liquid coolant through the coolant circulation path;
a plurality of sensors, each sensor configured to be circulated through a corresponding coolant circulation path of a corresponding coolant circulation system by a flowing liquid coolant of the corresponding coolant circulation path, the sensor configured to sense localized physical conditions of the liquid coolant at different locations along the corresponding coolant circulation path, wherein the sensor is in wireless communication with a controller; and
the controller configured to receive signals from the plurality of sensors, each received signal indicative of the localized physical conditions of associated liquid coolant at the different locations and adjust a condition of associated liquid coolant in response to the received signals.
3. The system of Embodiment 1, wherein the first subsystem comprises a compute subsystem comprising one or more compute dies each in thermal communication with the liquid coolant.
4. The system of Embodiment 3, wherein the one or more compute dies include one or more of a central processing unit (CPU), a graphic processing unite (GPU) and a tensor processing unit (TPU).
5. The system of any one of Embodiments 1 or 3-4, wherein the system further comprises:
a second coolant circulation system, comprising:
   a second coolant circulation path filled with a second liquid coolant in thermal communication with a second subsystem of the data center, and
   a second coolant circulator to flow the second liquid coolant through the second coolant circulation path;
a second sensor to be circulated through the second coolant circulation path by the flowing second liquid coolant, the second sensor configured to sense localized physical conditions of the second liquid coolant at different locations along the second circulation path, wherein the second sensor is in wireless communication with the controller; and
the controller configured to receive signals from the second sensor indicative of the localized physical conditions at the different locations along the second circulation path and adjust a condition of the second liquid coolant in response to the received signals from the second sensor.
6. The system of Embodiment 5, wherein the second subsystem is configured to be at different temperatures relative to the first subsystem during operation of the data center.
7. The system of Embodiment 5, wherein the second subsystem comprises a memory subsystem comprising one or more memory dies each in thermal communication with the second liquid coolant.
8. The system of Embodiment 7, wherein the one or more memory dies comprise one or more of a static random access memory (SRAM), a dynamic random access memory (DRAM) and a nonvolatile memory (NVM).
9. The system of Embodiment 5, wherein the second subsystem comprises a sensor subsystem, the sensor subsystem comprising one or more sensors each in thermal communication with the second liquid coolant.
10. The system of Embodiment 5, wherein the second subsystem comprises a timing device subsystem, the timing device subsystem comprising one or more timing devices each in thermal communication with the second liquid coolant.
11. The system of Embodiment 5, wherein the second subsystem comprises an interface subsystem, the interface subsystem comprising one or more communication interfaces each in thermal communication with the second liquid coolant.
12. The system of any one of Embodiments 1 or 3-11, wherein sensor comprises:
a sensor block comprising one or more of:
   a temperature sensor to measure a local temperature of the liquid coolant in contact with the sensor,
   a pressure sensor to measure a local pressure of the coolant in contact with the sensor, and
   a position sensor to sense position of the sensor within the coolant circulation path; and
a wireless communication block communicatively coupled with the controller via a wireless connection and configured to transmit data generated from the sensor block, the data comprising one or both of the localized temperature and the localized pressure measured by the sensor block and the associated positions measured by the position sensor.
13. The system of any one of Embodiments 1 or 3-12, wherein the sensor is enclosed in an enclosure contacting the liquid coolant.
14. The system of Embodiment 13, wherein the enclosure has a spherical shape.
15. The system of any one of Embodiments 1 or 3-14, wherein the sensor is powered by a secondary battery.
16. The system of Embodiment 13, wherein the sensor block is embedded on a surface of the enclosure.
17. The system of Embodiment 15, wherein a portion of the coolant circulation path is configured as a charging station for the secondary battery of the sensor.
18. The system of Embodiment 17, wherein the charging station comprises a wireless power transmitter, and wherein a transmitter coil of the wireless power transmitter is surrounding a dedicated portion of an outer surface of the coolant circulation path, the transmitter coil configured to transmit wireless power.
19. The system of Embodiment 18, wherein the sensor further comprises a wireless power receiver, the wireless power receiver comprising a receive coil configured to receive the transmitted wireless power.
20. The system of any one of Embodiments 17-19, wherein the controller is further configured to adjust a flow of the liquid coolant to park the sensor at the charging station for charging the secondary battery of the sensor.
21. The system of Embodiment 2, wherein the plurality of subsystems comprises a compute subsystem comprising one or more compute dies each in thermal communication with the liquid coolant included in a corresponding coolant circulation path.
22. The system of Embodiment 21, wherein the different locations include locations adjacent to and in thermal communication with the one or more compute dies.
23. The system of Embodiment 22, wherein the one or more compute dies include one or more of a central processing unit (CPU), a graphic processing unite (GPU) and a tensor processing unit (TPU).
24. The system of any one of Embodiments 2 or 21-23, wherein the plurality of subsystem comprises a memory subsystem comprising one or more memory dies each in thermal communication with the liquid coolant in a corresponding coolant circulation path.
25. The system of Embodiment 24, wherein the different locations include locations adjacent to and in thermal communication with the one or more memory dies.
26. The system of Embodiment 25, wherein the one or more memory dies comprise one or more of a static random access memory (SRAM), a dynamic random access memory (DRAM) and a nonvolatile memory (NVM).
27. The system of any one of Embodiments 2 or 21-26, wherein the plurality of subsystems further comprises an interface subsystem, the interface subsystem comprising one or more communication interfaces each in thermal communication with a liquid coolant included in a corresponding coolant circulation path.
28. The system of any one of Embodiments 2 or 21-27, wherein each sensor comprises:
a sensor block comprising one or more of:
   a temperature sensor to measure a local temperature of the liquid coolant in contact with the sensor,
   a pressure sensor to measure a local pressure of the coolant in contact with the sensor, and
   a position sensor to sense position of the sensor within the coolant circulation path; and
a wireless communication block communicatively coupled with the controller via a wireless connection and configured to transmit data generated from the sensor block, the data comprising one or both of the localized temperature and the localized pressure measured by the sensor block and the associated positions measured by the position sensor.
29. The system of any one of Embodiments 2 or 21-28, wherein each sensor is enclosed in an enclosure contacting the liquid coolant.
30. The system of Embodiment 29, wherein the enclosure has a spherical shape.
31. The system of any one of Embodiments 2 or 21-30, wherein the sensor block is embedded on a surface of the enclosure.
32. The system of any one of Embodiments 2 or 21-31, wherein each sensor is powered by a secondary battery.
33. The system of any one of Embodiments 2 or 21-32, wherein the coolant circulation path comprises a wireless power transmitter, and wherein a transmitter coil of the wireless power transmitter is surrounding a dedicated portion of an outer surface of the coolant circulation path, the transmitter coil configured to transmit wireless power.
34. The system of Embodiment 33, wherein the sensor further comprises a wireless power receiver, the wireless power receiver comprising a receive coil configured to receive the transmitted wireless power, wherein the controller is further configured to control the flow of the liquid coolant to locate the sensor to the dedicated portion.
35. The system of any one of the above Embodiments, wherein the localized physical conditions sensed by the sensor include one or both of a temperature and a pressure.
36. The system any one of the above Embodiments, wherein the condition of the liquid coolant adjusted includes one or both of a temperature and a flow rate.
37. The system of any one of the above Embodiments, wherein the different locations include locations adjacent to and in thermal communication with the one or more compute dies.
38. A data center, comprising:
a plurality of subsystems each configured to be monitored and controlled using an intelligent liquid cooling system, the intelligent liquid cooling system comprising:
a coolant circulation system, comprising:
   a coolant circulation path filled with a liquid coolant in thermal communication with a first subsystem of the data center, and
   a coolant circulator to flow the liquid coolant through the coolant circulation path;
a sensor to be circulated through the coolant circulation path by the flowing liquid coolant, the sensor configured to sense localized physical conditions of the liquid coolant at different locations along the coolant circulation path, wherein the sensor is in wireless communication with a controller; and
the controller configured to receive signals from the sensor indicative of the localized physical conditions at the different locations and adjust a condition of the liquid coolant in response to the received signals.
39. The data center of Embodiment 38, wherein the localized physical conditions sensed by the sensor include one or both of a temperature and a pressure.
40. The data center of Embodiment 38 or 39, wherein the condition of the liquid coolant adjusted includes one or more of a temperature and a flow rate.
41. The data center of any one of Embodiments 38-40, wherein the first subsystem comprises a compute subsystem comprising one or more compute dies each in thermal communication with the liquid coolant.
42. The data center of Embodiment 41, wherein the different locations include locations adjacent to and in thermal communication with the one or more compute dies.
43. The data center of Embodiment 41, wherein the one or more compute dies include one or more of a central processing unit (CPU), a graphic processing unite (GPU) and a tensor processing unit (TPU).
44. The data center of any one of Embodiments 38-43, wherein the intelligent cooling system further comprises:
a second coolant circulation system, comprising:
   a second coolant circulation path filled with a second liquid coolant in thermal communication with a second subsystem of the data center, and
   a second coolant circulator to flow the second liquid coolant through the second coolant circulation path;
a second sensor to be circulated through the second coolant circulation path by the flowing second liquid coolant, the second sensor configured to sense localized physical conditions of the second liquid coolant at different locations along the second circulation path, wherein the second sensor is in wireless communication with the controller; and
the controller configured to receive signals from the second sensor indicative of the localized physical conditions at the different locations along the second circulation path and adjust a condition of the second liquid coolant in response to the received signals from the second sensor.
45. The data center of Embodiment 44, wherein the second subsystem is configured to be at different temperatures relative to the first subsystem during operation of the data center.
46. The data center of Embodiment 44, wherein the second subsystem comprises a memory subsystem comprising one or more memory dies each in thermal communication with the second liquid coolant.
47. The data center of Embodiment 46, wherein the one or more memory dies comprise one or more of a static random access memory (SRAM), a dynamic random access memory (DRAM) and a nonvolatile memory (NVM).
48. The data center of any one of Embodiments 38-47, wherein the sensor comprises:
a sensor block comprising one or more of:
   a temperature sensor to measure a local temperature of the liquid coolant in contact with the sensor,
   a pressure sensor to measure a local pressure of the coolant in contact with the sensor, and
   a position sensor to sense position of the sensor within the coolant circulation path; and
a wireless communication block communicatively coupled with the controller via wireless connection, the wireless communication block configured to transmit data generated from the sensor block, the data comprising one or both of sensed temperatures and pressures and associated positions.
49. The data center of any one of Embodiments 38-48, wherein the sensor is enclosed in an enclosure contacting the liquid coolant.
50. The data center of Embodiment 49, wherein the enclosure has a spherical shape.
51. The data center of Embodiment 49, wherein the sensor block is embedded on a surface of the enclosure.
52. The data center of any one of Embodiments 38-51, wherein the sensor is powered by a secondary battery.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements, and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. An intelligent liquid cooling system for an electric vehicle, the system comprising:
a coolant circulation system, comprising:
a coolant circulation path filled with a liquid coolant in thermal communication with a first subsystem of the electric vehicle, and
a coolant circulator to flow the liquid coolant through the coolant circulation path;
a sensor to be circulated through the coolant circulation path by the flowing liquid coolant, the sensor configured to sense localized physical conditions of the liquid coolant at different locations along the coolant circulation path, wherein the sensor is in wireless communication with a controller; and
the controller configured to receive signals from the sensor indicative of the localized physical conditions at the different locations and adjust a condition of the liquid coolant in response to the received signals.

2. The system of claim 1, wherein the first subsystem comprises a secondary battery system including a plurality of secondary battery packs each in thermal communication with the liquid coolant.

3. The system of claim 2, wherein the different locations include locations adjacent and in thermal communication with different ones of the secondary battery packs.

4. The system of claim 1, wherein the localized physical conditions include one or both of a temperature and a pressure.

5. The system of claim 1, wherein the condition of the liquid coolant includes one or more of a temperature and a flow rate.

6. The system of claim 1, wherein the intelligent liquid cooling system further comprises:
a second coolant circulation system, the second coolant circulation system comprising:
a second coolant circulation path filled with a second liquid coolant in thermal communication with a second subsystem of the electric vehicle, and
a second coolant circulator to flow the second liquid coolant through the second coolant circulation path;
a second sensor to be circulated through the second coolant circulation path by the flowing second liquid coolant, the second sensor configured to sense localized physical conditions of the second liquid coolant at different locations along the second circulation path, wherein the second sensor is in wireless communication with the controller; and
the controller configured to receive signals from the second sensor indicative of the localized physical conditions at the different locations along the second circulation path and adjust a condition of the second liquid coolant in response to the received signals from the second sensor.

7. The system of claim 6, wherein the second subsystem comprises an electric component system, the second subsystem configured to be at different temperatures relative to the first subsystem during operation of the electric vehicle.

8. The system of claim 1, wherein the coolant circulation system further comprises:
a coolant reservoir to store the liquid coolant;
an inlet at one end of the coolant circulation path; and
an outlet at another end of the coolant circulation path,
wherein the coolant circulator is configured to circulate the liquid coolant from the coolant reservoir into the inlet and return the liquid coolant from the outlet back into the coolant reservoir.

9. The system of claim 1, wherein the sensor comprises:
a sensor block comprising one or more of:
a temperature sensor to measure a local temperature of the liquid coolant in contact with the sensor,
a pressure sensor to measure a local pressure of the coolant in contact with the sensor, and
a position sensor to measure position of the sensor within the coolant circulation path; and
a wireless communication block communicatively coupled with the controller via a wireless connection and configured to transmit data generated from the sensor block, the data comprising one or both of the local temperature and the local pressure measured by the sensor block and associated positions.

10. The system of claim 9, wherein the sensor is enclosed in an enclosure contacting the liquid coolant.

11. The system of claim 10, wherein the sensor is powered by a secondary battery.

12. The system of claim 11, wherein the secondary battery is enclosed in the enclosure.

13. The system of claim 12, wherein the enclosure has a spherical shape.

14. The system of claim 12, wherein the sensor block is embedded on a surface of the enclosure.

15. The system of claim 11, wherein a portion of the coolant circulation path is configured as a charging station for the secondary battery of the sensor.

16. The system of claim 15, wherein the charging station comprises a wireless power transmitter, and wherein a transmitter coil of the wireless power transmitter is surrounding a dedicated portion of an outer surface of the coolant circulation path, the transmitter coil configured to transmit wireless power.

17. The system of claim 16, wherein the sensor further comprises a wireless power receiver, the wireless power receiver comprising a receive coil configured to receive the transmitted wireless power.

18. The system of claim 15, wherein the controller is further configured to control the flow of the liquid coolant to park the sensor to the charging station for charging the secondary battery of the sensor.

19. The system of claim 1, wherein the sensor comprises an antenna and a radio frequency system configured to establish the wireless communication with the controller.

20. The system of claim 1, the coolant circulation system further comprises an evaporator configured to remove heat from the liquid coolant.

21. The system of claim 1, wherein the controller is configured to identify a hot spot of the first subsystem by determining whether the sensed localized physical conditions at a specific location along the coolant circulation path is different from the sensed localized physical conditions at other locations of the subsystem.

22. The system of claim 1, wherein the sensor comprises an analog to digital converter, wherein the analog to digital converter is configured to convert the sensed physical conditions into digital signals to transmit to the controller.

23.-55. (canceled)
